(19) United States
(12) Patent Application Publication
(10) Pub. No.: US 2026/0068378 A1
(43) Pub. Date: Mar. 5, 2026

(54) METHOD FOR MANUFACTURING INDIVIDUALIZED-PIECE-FILM AND INDIVIDUALIZED-PIECE-FILM, AND METHOD FOR MANUFACTURING DISPLAY DEVICE AND DISPLAY DEVICE

(71) Applicant: DEXERIALS CORPORATION, Shimotsuke-shi, Tochigi (JP)

(72) Inventors: Reiji TSUKAO, Tochigi (JP); Naoki HAYASHI, Tochigi (JP); Daiki NODA, Tochigi (JP); Kazumu WATANABE, Tochigi (JP); Toshiki SHIRAIWA, Tochigi (JP)

(73) Assignee: DEXERIALS CORPORATION, Shimotsuke-shi, Tochigi (JP)

(21) Appl. No.: 19/108,211

(22) PCT Filed: Aug. 2, 2023
(86) PCT No.: PCT/JP2023/028275

§ 371 Date: Mar. 3, 2025

(30) Foreign Application Priority Data
Sep. 13, 2022 (JP) 2022-145317

(51) Int. Cl. H10H 29/24; H10H 29/01; H10H 29/49

(52) U.S. Cl. CPC H10H 29/24; H10H 29/0364; H10H 29/49

(57) ABSTRACT

A method for manufacturing an individualized-piece-film that can obtain excellent workability of individualized pieces, an individualized-piece-film, and a display device. The method irradiates a laser light from a base material side to an anisotropic conductive film formed on a base material to remove the anisotropic conductive film in the irradiated area (removal portion), thereby forming individualized pieces of a predetermined shape. The thickness of the anisotropic conductive film is 1 μm or more and 10 μm or less, the melt viscosity of the anisotropic conductive film at 30° C. is 2,000 Pa*s or more and 800,000 Pa*s or less, and 90% or more of the conductive particles in the anisotropic conductive film are present at an average of the center positions of the conductive particles in the thickness direction of the anisotropic conductive film.

### TECHNICAL FIELD

This technology relates to a method for manufacturing an individualized-piece-film to individualize a connection film such as anisotropic conductive film (ACF) and adhesive film (NCF: non conductive film), and to an individualized-piece-film. This technology also relates to a method for manufacturing a display device that connects and arranges light-emitting elements via individualized-piece-film, and to a display device. In particular, this technology relates to a method for manufacturing a display device that connects and arranges LED elements such as mini-LEDs (light emitting diodes) and micro-LEDs, and to the display device. This application claims priority based on Japanese Patent Application No. 2022-145317, which was filed in Japan on Sep. 13, 2022, and this application is hereby incorporated by reference.

### BACKGROUND ART

The development of mini-LED and micro-LED displays is attracting attention as next-generation displays. Mini-LED and micro-LED displays are composed of arrays of minute light-emitting elements on a substrate, so they can omit the backlight required for LCD displays, making it possible to make the display thinner, and they can also achieve a wider color gamut, higher resolution, and lower power consumption.

Patent Document 1 discloses a method of joining LEDs with ACF. In the method described in Patent Document 1, the ACF is entirely pasted to an element mounting surface of a substrate, so the adhesive resin of the ACF and conductive particles remain between adjacent LEDs. Therefore, in a case where the light-emitting element array requires light transmissive properties, the transmission of light will be blocked, and it will not be possible to obtain excellent light transmissive properties. In addition, if the film is applied to the entire surface of the substrate, there are concerns that it will have a negative impact on productivity, such as increasing the number of repair man-hours when a defect occurs.

On the other hand, when ACF is attached only directly below the LEDs, the adhesive resin and conductive particles of the ACF do not remain between adjacent LEDs, and do not obstruct the transmission of light, so light transmissive properties can be obtained.

However, it is difficult to attach connection films such as ACF only directly below the LEDs. For example, when the individualized pieces are attached to the substrate after forming the individualized pieces of the connection film, if the shape of the individualized pieces is poor, the transferability of the individualized pieces to the substrate or LED will deteriorate, and the tact time for display manufacturing will deteriorate.

### CITATION LIST

### Patent Literature

Patent document 1: U.S. Patent Application Publication No. 2015/0255505

### SUMMARY OF INVENTION

### Technical Problem

The present technology is proposed in light of this conventional situation and provides a method for manufacturing an individualized-piece-film that can obtain excellent workability of individualized pieces, as well as a method for manufacturing a display device and a display device.

### Solution to Problem

A method for manufacturing an individualized-piece-film according to the present technology irradiates a laser light from a base material side to an anisotropic conductive film formed on a base material to remove the anisotropic conductive film in the irradiated area, thereby forming an individualized piece of a predetermined shape composed of the anisotropic conductive film on the base material, wherein the thickness of the anisotropic conductive film is 0.9 times or more and 8 times or less of the particle diameter of the conductive particles in the anisotropic conductive film, and the melt viscosity of the anisotropic conductive film at 30° C. is 2,000 Pa*s or more and 800,000 Pa*s or less.

An individualized-piece-film according to the present technology includes an individualized piece of a predetermined shape composed of an anisotropic conductive film, wherein the thickness of the anisotropic conductive film is 0.9 times or more and 8 times or less of the particle diameter of the conductive particles in the anisotropic conductive film, and the melt viscosity of the anisotropic conductive film at 30° C. is 2,000 Pa*s or more and 800,000 Pa*s or less.

A method for manufacturing a display device according to the present technology includes: a formation step of irradiating a laser light from a base material side to an anisotropic conductive film formed on a base material to remove the anisotropic conductive film in the irradiated area, thereby forming an individualized piece of a predetermined shape composed of the anisotropic conductive film on the base material; a transfer step of transferring the individualized pieces of the predetermined shape to a predetermined position on a wiring substrate or to an electrode surface of a light-emitting element; and a mounting step of mounting the light-emitting element to the wiring substrate via the transferred individualized pieces, wherein the thickness of the anisotropic conductive film is 0.9 times or more and 8 times or less of the particle diameter of the conductive particles in the anisotropic conductive film, and the melt viscosity of the anisotropic conductive film at 30° C. is 2,000 Pa*s or more and 800,000 Pa*s or less.

A method for manufacturing a connection structure according to the present technology includes: a formation step of irradiating a laser light from a base material side to an anisotropic conductive film formed on a base material to remove the anisotropic conductive film in the irradiated area, thereby forming an individualized piece of a predetermined shape composed of the anisotropic conductive film on the base material; a transfer step of transferring the individualized piece of the predetermined shape to a predetermined position of a first electronic component; and a mounting step of mounting a second electronic component to a predetermined position of the wiring substrate, wherein the thickness of the anisotropic conductive film is 0.9 times or more and 8 times or less of the particle diameter of the conductive particles in the anisotropic conductive film, and the melt viscosity of the anisotropic conductive film at 30° C. is 2,000 Pa*s or more and 800,000 Pa*s or less.

A display device according to the present technology includes: a plurality of light-emitting elements; a wiring substrate on which the light-emitting elements are arranged; and a cured film that connects the plurality of light-emitting elements to the wiring substrate, wherein the cured film is made by curing individualized pieces of a predetermined shape composed of an anisotropic conductive film, the thickness of the anisotropic conductive film is 0.9 times or more and 8 times or less of the particle diameter of the conductive particles in the anisotropic conductive film, and the melt viscosity of the anisotropic conductive film at 30° C. is 2,000 Pa*s or more and 800,000 Pa*s or less.

A connection structure according to the present technology includes: a first electronic component; a second electronic component; and a cured film connecting the first electronic component and the second electronic component, wherein the cured film is made by curing individualized pieces of a predetermined shape composed of an anisotropic conductive film, the thickness of the anisotropic conductive film is 0.9 times or more and 8 times or less of the particle diameter of the conductive particles in the anisotropic conductive film, and the melt viscosity of the anisotropic conductive film at 30° C. is 2,000 Pa*s or more and 800,000 Pa*s or less.

### Advantageous Effects of Invention

According to the present technology, it is possible to obtain excellent workability of individualized pieces and to improve tact time.

### BRIEF DESCRIPTION OF DRAWINGS

FIG. 1 is a schematic cross-sectional view of an anisotropic conductive film, in which FIG. 1 (A) shows a state in which 90% or more of the conductive particles are present at a reference value and the reference value is close to the base material side, FIG. 1 (B) shows a state in which 90% or more of the conductive particles are present at a reference value and the reference value is close to the opposite side of the base material, and FIG. 1 (C) shows a state in which the conductive particles are dispersed in the thickness direction.

FIG. 2 is a schematic view illustrating an example of a laser lift-off device according to the present embodiment.

FIG. 3 is a view used to explain an example of a method for manufacturing an individualized-piece-film, which is shown as Implementation 1, in which FIG. 3 (A) shows an anisotropic conductive film substrate on which an anisotropic conductive film is formed on a base material, FIG. 3 (B) shows the removal portion being peeled off in the first direction, FIG. 3 (C) shows the removal portion being peeled off in the second direction, and FIG. 3 (D) shows the individualized-piece-film on which individualized pieces of the anisotropic conductive film are formed on a base material.

FIG. 4 (B) is a schematic diagram showing an example of laser light passing through the openings in the mask.

FIG. 5 (A) is a microscope photograph showing an example of a piece that has burrs formed during an individualization process, and FIG. 5 (B) is a microscope photograph showing an example of a piece that has curling or chipping formed during the transfer of the individualized pieces.

FIG. 6 (A) is a schematic diagram showing an example of a mask having a light-shielding portion in the window of the opening, and FIG. 6 (B) is a schematic diagram showing an example of laser light irradiation passing through the opening of the mask.

FIG. 7 is a schematic diagram showing an example of a mask having multiple light-shielding portions in the window of the opening.

FIG. 8 is a schematic diagram showing examples of the shape of the opening of the mask, where FIG. 8 (A) shows a mask having a rectangular light-shielding portion within the window of the opening, FIG. 8 (B) shows a mask having a square light-shielding portion within the window of the opening, FIG. 8 (C) shows a mask having a rectangular light-shielding portion with rounded corners within the window of the opening, and FIG. 8 (D) shows a mask having a circular light-shielding portion within the window of the opening.

FIG. 9 is a schematic cross-sectional view of the anisotropic conductive film provided on the base material.

FIG. 10 is a cross-sectional view schematically illustrating a state in which an individualized-piece-film and a wiring substrate face each other.

FIG. 11 is a cross-sectional view schematically illustrating a state in which the individualized pieces of the anisotropic conductive film are transferred to and arranged in predetermined positions on the wiring substrate by irradiating laser light from the base material side.

FIG. 12 is a cross-sectional view schematically illustrating a state in which light-emitting elements are mounted on the individualized pieces arranged in predetermined positions on the wiring substrate.

FIG. 13 is a cross-sectional view schematically illustrating a state in which the individualized pieces of the anisotropic conductive film are transferred to and arranged in the electrode position of the wiring substrate by irradiating laser light from the base material side.

FIG. 14 is a cross-sectional view schematically illustrating a state in which light-emitting elements are mounted on the individualized pieces arranged on the wiring substrate in units of electrodes.

FIG. 15 is a cross-sectional view schematically illustrating a state in which individualized pieces of the anisotropic conductive film provided on the base material and light-emitting elements arranged on the transfer substrate face each other.

FIG. 16 is a cross-sectional view schematically illustrating a state in which individualized pieces of the anisotropic conductive film are transferred to light-emitting elements arranged on the transfer substrate by irradiating laser light from the base material side.

FIG. 17 is a cross-sectional view schematically illustrating a state in which light-emitting elements to which the individualized pieces have been transferred are retransferred to a wiring substrate.

FIG. 18 schematically illustrates a fabrication method of a mounting body, in which FIG. 18 (A) shows the step of preparing individualized pieces, FIG. 18 (B) shows the step of transferring the individualized pieces to a substrate, FIG. 18 (C) shows the step of temporarily fixing a μLED element, and FIG. 18 (D) shows the step of pressure bonding the μLED element.

FIG. 19 is a plan view schematically illustrating an evaluation substrate for a lighting test.

FIG. 20 (A) is a plan view schematically illustrating an electrode surface of the μLED element, and FIG. 20 (B) is a plan view schematically illustrating a μLED element mounted on an evaluation substrate.

### DESCRIPTION OF EMBODIMENTS

With reference to the drawings, the embodiments of the present technology are described in detail below in the following order.
1. METHOD FOR MANUFACTURING INDIVIDUALIZED-PIECE-FILM
2. INDIVIDUALIZED-PIECE-FILM
3. METHOD FOR MANUFACTURING DISPLAY DEVICE
4. DISPLAY DEVICE
5. EXAMPLES

### 1. Method for Manufacturing Individualized-Piece-Film

The method for manufacturing an individualized-piece-film in this embodiment includes irradiating an anisotropic conductive film formed on a base material with laser light from the base material side to remove the anisotropic conductive film in the irradiated area, thereby forming an individualized piece of a predetermined shape composed of the anisotropic conductive film on the base material. Here, by making the thickness of the anisotropic conductive film and the melt viscosity of the anisotropic conductive film at 30° C. within the following ranges, it is possible to obtain excellent workability of individualized pieces.

The thickness of the anisotropic conductive film is preferably 0.9 times or more and 8 times or less of the particle diameter of the conductive particles in the anisotropic conductive film, more preferably 1 times or more and 7 times or less of the particle diameter of the conductive particles in the anisotropic conductive film, and even more preferably 1.5 times or more and 5 times or less of the particle diameter of the conductive particles in the anisotropic conductive film. The thickness of the anisotropic conductive film is preferably 1 μm or more and 10 μm or less, more preferably 1 μm or more and 6 μm or less, and even more preferably 2 μm or more and 4 μm or less. By making the thickness of the anisotropic conductive film within the above range, it becomes easier to tear the anisotropic conductive film apart by irradiating it with laser light, and it is possible to obtain individualized pieces with a shape that matches the shape of the mask. The thickness of the anisotropic conductive film can be measured using a known micrometer or digital thickness gauge, for example by measuring at ten or more locations and calculating the average.

The melt viscosity of the anisotropic conductive film at 30° C. is preferably 2,000 Pa*s or more and 800,000 Pa*s or less, more preferably 5,000 Pa*s or more and 500,000 Pa*s or less, and even more preferably 10,000 Pa*s or more and 300,000 Pa*s or less. If the viscosity is too low, the individualized pieces will shrink after laser irradiation, making it difficult to maintain the film on the individualized pieces, and if the viscosity is too high, the anisotropic conductive film will be too strong, making it difficult to remove it by laser irradiation. The melt viscosity of the anisotropic conductive film at 30° C. can be measured using a rheometer, e.g., with a measurement frequency of 10 Hz.

In addition, it is preferable that 90% or more of the conductive particles in the anisotropic conductive film present at the average of the center positions of the conductive particles in the thickness direction of the anisotropic conductive film, and the presence ratio is more preferably 92% or more, and even more preferably 95% or more. This prevents irregularities in the degree of ablation and allows the production of individualized pieces with the same shape as the mask. The presence ratio of the conductive particles in relation to the average of the center positions of the conductive particles in the thickness direction of the anisotropic conductive film can be calculated by observing the cross-section of the anisotropic conductive film under a microscope and measuring the conductive particles. For example, the cross-section of the anisotropic conductive film containing 200 or more conductive particles in a predetermined range is observed, the average of the center positions of the conductive particles in the cross-section is taken as the reference value (reference line), and then, within the predetermined range, the presence ratio of the conductive particles having a part of the outer diameter crossing the reference value (the shortest distance between the reference line and the edge of the conductive particle is 0.5 times or less the particle diameter) is then calculated. In this case, the reference line can be considered to be roughly parallel to the line of the film surface in the film cross-section. In other words, the center position of the conductive particles in the thickness direction represents the presence ratio of the conductive particles in the predetermined range relative to the reference line.

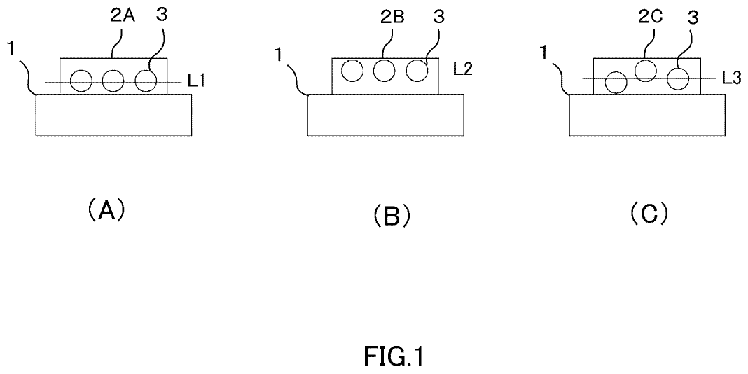

FIG. 1 is a schematic cross-sectional view of an anisotropic conductive film, in which FIG. 1 (A) shows a state in which 90% or more of the conductive particles are present at a reference value and the reference value is close to the base material side, FIG. 1 (B) shows a state in which 90% or more of the conductive particles are present at a reference value and the reference value is close to the opposite side of the base material, and FIG. 1 (C) shows a state in which the conductive particles are dispersed in the thickness direction.

As shown in FIGS. 1 (A) to 1 (C), the anisotropic conductive films 2A to 2C are formed on a base material 1. The base material 1 only needs to be transparent to laser light, and quartz glass, which has a high light transmissivity across the entire wavelength range, is particularly preferable.

As shown in FIGS. 1 (A) and 1 (B), it is preferable that 90% or more of the conductive particles 3 in the anisotropic conductive films 2A, 2B present at the reference value (reference lines L1 and L2). This prevents the occurrence of burrs, chips, shrinkage, and stretching, and allows the production of individualized pieces with the same shape as the mask. On the other hand, as shown in FIG. 1 (C), in the case of an anisotropic conductive film 2C, where the conductive particles 3 are dispersed in the thickness direction and less than 90% of the conductive particles 3 present at the reference value (reference line L3), irregularities in the degree of ablation may occur during peeling by laser irradiation, and it may be difficult to obtain individualized pieces with the same shape as the mask.

### Anisotropic Conductive Film

The binder for the anisotropic conductive film is not particularly limited as long as it cures with energy such as heat and light and can be selected as appropriate from thermo-curable binders, photo-curable binders, and thermo/photo-curable binders, for example.

Examples of the thermo-curable binder may include thermal anionic polymerization type resin compositions containing epoxy compounds and thermal anionic polymerization initiators, thermal cationic polymerization resin compositions containing epoxy compounds and thermal cationic polymerization initiators, and thermal radical polymerization type resin compositions containing (meth)acrylate compounds and thermal radical polymerization initiators. Examples of the photo-curable binder may include photo cationic polymerization type resin compositions containing epoxy compounds and photo cationic polymerization initiators, and thermal radical polymerization type resin compositions containing (meth)acrylate compounds and photo radical polymerization initiators. Examples of the thermo/photo-curable binder may include mixtures of thermo-curable binders and photo-curable binders. The term (meth)acrylate compound refers to both acrylic monomers (oligomers) and methacrylic monomers (oligomers).

### Thermal Cationic Polymerization Resin Composition

As a specific example of the thermo-curable binder, a thermal cationic polymerization resin composition that includes film-forming resins, epoxy compounds, and thermal cationic polymerization initiators will be explained in the following.

As the film-forming resin, e.g., a high-molecular-weight resin with an average molecular weight of 10,000 or more is used, and from the perspective of film-forming properties, an average molecular weight of around 10,000 to 80,000 is preferable. Examples of the film-forming resin may include butyral resin, phenoxy resin, polyester resin, polyurethane resin, polyester-urethane resin, acryl resin, and polyimide resin, and these can be used individually or in combination with two or more. Among these, butyral resin is preferable from the perspective of film formation conditions and connection reliability. The content of the film-forming resin is preferably 20 to 70 parts by mass, more preferably 30 to 60 parts by mass or less, and even more preferably 45 to 55 parts by mass for 100 parts by mass of thermo-curable binder.

The epoxy compound is not limited as long as it has one or more epoxy groups in its molecules, and can be, e.g., bisphenol A epoxy resin, bisphenol F epoxy resin, and the like or a urethane-modified epoxy resin. Among these, hydrogenated bisphenol A glycidyl ether can be preferably used. A specific example of hydrogenated bisphenol A glycidyl ether is “YX8000 (product name)” manufactured by Mitsubishi Chemical Corporation. The content of the epoxy compound is preferably 30 to 60 parts by mass, more preferably 35 to 55 parts by mass or less, and even more preferably 35 to 45 parts by mass for 100 parts by mass of thermo-curable binder.

As the thermal cationic polymerization initiator, a known thermal cationic polymerization initiator for epoxy compounds can be used, and examples may include an initiator that generates an acid that can cause cationic polymerization of cationic polymerization-type compounds by heat, such as a known iodonium salt, sulfonium salt, phosphonium salt, and ferrocene among others. Among these, aromatic sulfonium salts, which show good latency for temperature, can be used. A specific example of an aromatic sulfonium salt polymerization initiator is “SI-60L (product name)” manufactured by Sanshin Chemical Industry. The content of the thermal cationic polymerization initiator is preferably 1 to 20 parts by mass, more preferably 5 to 15 parts by mass or less, and even more preferably 8 to 12 parts by mass for 100 parts by mass of thermo-curable binder.

In addition, other additives may be blended with the thermo-curable binder as required and examples of the additive may include rubber components, inorganic fillers, silane coupling agents, monomers for dilution, fillers, softeners, colorants, flame retardants, and thixotropic agents, among others.

The rubber component is not particularly limited as long as it is an elastomer having high cushioning (impact-canceling) properties, and specific examples may include acryl rubber, silicone rubber, butadiene rubber, and polyurethane resin (polyurethane elastomer). Examples of the inorganic filler may include silica, talc, titanium oxide, calcium carbonate, and magnesium oxide. One inorganic filler may be used alone or two or more inorganic fillers may be used in combination.

The thermo-curable binder containing such a composition can suppress the curing reaction when forming the individualized pieces using laser light and can be quickly cured by heat during thermocompression bonding.

### Conductive Particles

The conductive particles can be selected as appropriate from those used in known anisotropic conductive films. For example, the conductive particles may be metal particles including nickel (melting point: 1,455° C.), copper (melting point: 1,085° C.), silver (melting point: 961.8° C.), gold (melting point: 1,064° C.), palladium (melting point: 1,555° C.), tin (melting point 231.9° C.), nickel boride (melting point 1,230° C.), ruthenium (melting point 2,334° C.), and solder, which is a tin alloy. In addition, further examples may include metal-coated metal particles, which are metal particles the surface of which is coated with a metal such as nickel, copper, silver, gold, palladium, tin, nickel boride, and ruthenium. In addition, further examples may include metal-coated resin particles, which are resin particles including at least one monomer selected from polyamide, polybenzoguanamine, styrene, and divinylbenzene as a monomer unit and the surface of which is coated with a metal such as nickel, copper, silver, gold, palladium, tin, nickel boride, and ruthenium. In addition, further examples may include metal-coated inorganic particles, which are inorganic particles such as silica, alumina, barium titanate, zirconia, carbon black, silicate glass, borosilicate glass, lead glass, soda-lime glass, and alumina-silicate glass, the surface of which is coated with a metal such as nickel, copper, silver, gold, palladium, tin, nickel boride, and ruthenium. The metal coating layer of the metal-coated resin particles and metal-coated inorganic particles may be a single layer or a multilayer of different metals.

The conductive particles may also be covered with an insulating resin layer or insulating particles such as resin particles and insulating particles to provide an insulating treatment. The particle diameter of the conductive particles does not include the insulating layer. The particle diameter of the conductive particles is changed appropriately depending on the areas of the optical elements to be mounted, the electrodes on the wiring substrate, and the bumps, among others, but is preferably 1 to 30 μm, more preferably 1 to 10 μm, and particularly preferably 1 to 3 μm. For example, when used for mounting micro LED elements, since the areas of the electrodes and the bumps are small, the particle diameter of the conductive particles is preferably 1 to 3 μm, more preferably 1 to 2.5 μm, particularly preferably 1 to 2.2 μm. The particle diameter can be determined by measuring the average of 200 or more particles using a microscope (optical microscope, metal microscope, and electron microscope, among others).

In addition, in the cases where the conductive particles are the aforementioned metal-coated resin particles or metal-coated inorganic particles, i.e., resin particles or inorganic particles coated with a metal, the thickness of the metal coating is preferably 0.005 μm or more, more preferably 0.01 μm or more, and preferably 10 μm or less, more preferably 1 μm or less, and even more preferably 0.3 μm or less. In the cases where the metal coating is multi-layered, this coating thickness is the thickness of the entire metal coating. If the metal coating thickness is above the lower limit and below the upper limit given above, it is easy to obtain sufficient conductivity, and the conductive particles do not become too hard, making it easy to utilize the characteristics of the resin particles and inorganic particles mentioned above.

The metal coating thickness can be measured, e.g., by observing the cross-section of the conductive particle using a transmission electron microscope (TEM). Regarding the above coating thickness, it is preferable to calculate the average of the coating thickness of five arbitrary coating thicknesses as the coating thickness of a single conductive particle, and it is even more preferable to calculate the average of the thickness of the entire coated area as the coating thickness of a single conductive particle. The above coating thickness is preferably obtained by calculating the average of the coating thickness of each of ten arbitrary conductive particles.

In addition, examples of the shape of conductive particles may include spherical, elliptical, spike-shaped, and irregular shapes. Among these, spherical conductive particles are preferred because they are easy to control in terms of particle diameter and particle size distribution. In addition, conductive particles may have protrusions on their front surface to improve connectivity.

In the anisotropic conductive film, the conductive particles are preferably arranged in a surface direction. By arranging conductive particles in a surface direction, the particle areal density becomes uniform, and conductivity and insulation properties can be improved. An example of the state in which the conductive particles are arranged in a surface direction is a planar lattice pattern that has one or more array axes on which the conductive particles are arranged in a predetermined direction at a predetermined pitch, including oblique lattices, hexagonal lattices, square lattices, rectangular lattices, and parallelepiped lattices. The state in which the conductive particles are arranged in a surface direction may also be said that the conductive particles are arranged in the plane view of the film. In addition, the arrangement of conductive particles in a surface direction may be random, and the planar lattice pattern may have multiple regions that differ from each other.

The particle areal density of the anisotropic conductive film can be designed appropriately according to the size of the connection electrode, and the lower limit of the particle areal density can be set to 500 particles/mm² or more, 20,000 particles/mm² or more, 40,000 particles/mm² or more, or 50,000 particles/mm² or more, and the upper limit of the particle areal density can be set to 1,500,000 particles/mm² or less, 1,000,000 particles/mm² or less, 500,000 particles/mm² or less, or 100,000 particles/mm² or less. This allows for excellent conductivity and insulation even when the size of the connection electrode is small. The particle areal density of the anisotropic conductive films is the density of the array portion of conductive particles when the film is formed during manufacturing. When calculating the number density of particles from multiple individualized pieces, the particle areal density can be calculated from the area including the individualized pieces and the spaces minus the spaces between individualized pieces, and the number of particles.

The anisotropic conductive film having a film-shape makes it easier to provide the anisotropic conductive film on the base material. From the perspective of handleability, a release film such as polyethylene terephthalate film may be attached to one or both sides of the anisotropic conductive film. In addition, the anisotropic conductive film may be laminated with adhesive layers or pressure-sensitive adhesive layers that do not contain conductive particles, and the number of layers and the laminated surface can be selected as appropriate according to the target and purpose.

Examples of the method for manufacturing the anisotropic conductive film may include, e.g., applying a solution of anisotropic conductive adhesive on a base material and drying the solution, or forming an adhesive layer that does not contain conductive particles on a base material and fixing the conductive particles to the resulting adhesive layer.

### Laser Lift-Off Device

For example, a laser lift-off (LLO) device can be used as a device for forming individualized pieces of a predetermined shape by irradiating laser light. The laser lift-off device is a device that irradiates a material layer formed on a base material with laser light and peels off the material layer from the base material; an example of the laser lift-off device is “Invisi LUM-XTR (product name)” manufactured by Shin-Etsu Chemical.

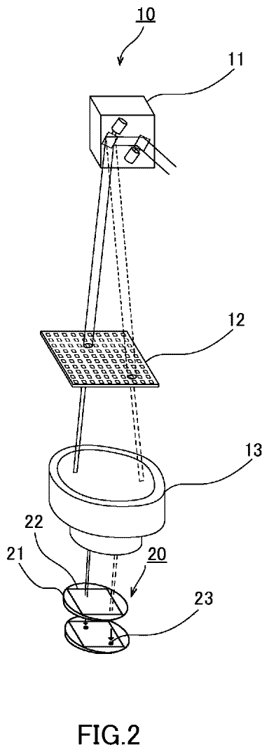

FIG. 2 is a schematic view illustrating an example of a laser lift-off device according to the present embodiment. As shown in FIG. 2, the laser lift-off device 10 includes a laser scanner 11 that scans the optical axis of the laser light, a mask 12 that has a plurality of openings of a predetermined shape and predetermined pitch, a projection lens 13 that reduces and projects the laser light onto the donor substrate, a donor stage that holds the donor substrate, and a receptor stage that holds the receptor substrate. In the formation of an individualized-piece-film, an anisotropic conductive film substrate 20 with an anisotropic conductive film 22 formed on a base material 21 is held on the donor stage as a donor substrate, and the removal portion 23 of the anisotropic conductive film separated from the anisotropic conductive film substrate 20 is received by the receptor substrate.

As a laser device, e.g., an excimer laser that oscillates laser light with a wavelength of 180 nm to 360 nm can be used. The oscillation wavelengths of excimer lasers are, e.g., 193, 248, 308, and 351 nm, and an appropriate oscillation wavelength can be selected from these according to the light absorption properties of the material of the anisotropic conductive film 22. In addition, if a release material is placed between the base material 21 and the anisotropic conductive film 22, the oscillation wavelength can be selected appropriately according to the light absorption properties of the release material.

The laser scanner 11 has a scanning mirror consisting of, e.g., a two-axis galvanometer scanner, which directs the laser light toward the opening on the mask 12 and scans the optical axis of the laser light in the X-axis and Y-axis directions while controlling the pulse irradiation of the laser light.

The mask 12 has a pattern of an array of windows of a predetermined size at a predetermined pitch so that the irradiation of laser light at the interface between the base material 21 and the anisotropic conductive film 22 has a predetermined shape. For example, the mask has a pattern applied by chrome plating, and the window portions that have not been chrome-plated allow laser light to pass through, while the chrome-plated portions block laser light.

The projection lens 13 projects laser light that has passed through the pattern of the mask 12 onto the donor substrate. In addition, the donor stage has a moving mechanism that moves it at least in the X and Y axes to move the irradiation position of laser light on the donor substrate.

The laser lift-off device 10 constitutes a scanning type reduction projection optical device that includes the laser scanner 11, the mask 12, the field lens disposed between the laser scanner 11 and the mask 12, and the reduction projection lens 13 that is telecentric at least on the image side.

The incident light from the laser device enters the telescope optics and is propagated to the laser scanner 11 installed at the rear of the telescope optics. The laser light just before it enters the laser scanner 11 is adjusted by the telescope optics so that it becomes roughly parallel light at any position within the movement range of the X-axis and Y-axis of the donor stage, and enters the laser scanner 11 at roughly the same size and the same angle (perpendicular).

The laser light that passes through the laser scanner 11 enters the mask 12 via the field lens, and the laser light that passes through the pattern of the mask 12 enters the projection lens 13. The laser light emitted from the projection lens 13 enters from the base material 21 side and is projected accurately in the shape of the opening of the mask 12 onto the predetermined position at the interface between the base material 21 and the anisotropic conductive film 22.

The pulse energy of the laser light that is imaged at the interface between the base material 21 and the anisotropic conductive film 22 is preferably 0.001 to 2 J, more preferably 0.01 to 1.5 J, and even more preferably 0.1 to 1 J. The fluence is preferably 0.001 to 2 J/cm², more preferably 0.01 to 1 J/cm², and even more preferably 0.05 to 0.5 J/cm². The pulse width (irradiation time) is preferably 0.01 to 1×10⁹ picoseconds, more preferably 0.1 to 1×10⁷ picoseconds, and even more preferably 1 to 1×10⁵ picoseconds. The pulse frequency is preferably 0.1 to 10,000 Hz, more preferably 1 to 1,000 Hz, and even more preferably 1 to 100 Hz. The number of irradiation pulses is preferably between 1 and 30,000,000.

Such a laser lift-off device can generate an impact wave at the boundary between the base material 21 and the anisotropic conductive film 22, peel off the removal portion 23 of the anisotropic conductive film 22 from the base material 21, and form individualized pieces of a predetermined shape with high accuracy and high efficiency by the remaining portion on the base material 21, thereby achieving excellent workability. In addition, because the effect of the irradiation of laser light on the individualized pieces of the predetermined shape is small, the reaction rate of the individualized pieces can be made to be 25% or less, preferably 20% or less, and even more preferably 15% or less, so that excellent transferability can be obtained.

The reaction rates of the curable resin film before laser irradiation and the individualized pieces obtained after laser irradiation can be measured using FT-IR, e.g., by determining the reduction rate of the reactive groups. If the individualized pieces are small, the reaction rate can be measured from the edge of the film where the individualized pieces have been punched out. For example, it is preferable to measure the reaction rate of the individualized pieces before laser irradiation within 8 hours of taking them out of the refrigerator and at room temperature and to measure the reaction rate of the individualized pieces after laser irradiation within 8 hours at room temperature after laser irradiation.

In the case of a curable resin film that uses the reaction of an epoxy compound, e.g., the reaction rate can be measured using FT-IR by preparing a sample as follows. First, a cured individualized piece is sampled using a pen-type cutter with a sharp tip. Next, the sample is placed on a diamond cell, flattened thinly on the diamond cell, and attached to a sample holder to set in the main unit of the device.

The diamond cell used for this measurement is a set of two pieces, and the sample is sandwiched between the two cell plates and tightened and crushed. After that, the measurement is carried out using one of the cell plates with the sample adhered. The amount of sample required for measurement is extremely small. If the sample is too large, it will not be possible to crush it thinly, so the measurement will be carried out with the sample film thickness in its thick state. As a result, the baseline will drop or become slanted, and the peaks will saturate, making it difficult to analyze the spectrum. Therefore, it is preferable to sample by an amount that can be adjusted to a thin state on the diamond cell (e.g., a film thickness of 10 μm or less).

Detector sensitivity is greatly improved by cooling, so the detector is cooled with liquid nitrogen for approximately 30 minutes prior to measurement. The FT-IR measurement conditions are set as follows.
Measurement method: transmission type measurement
Measurement temperature: 25° C.
Measurement humidity: 60% or less
Measurement time: 12 sec
Spectral range of detector: 4,000 to 700 cm⁻¹

Then, the diamond cell is set in the infrared microscope to perform background measurement. The background measurement position should be as close as possible to the sample measurement position to obtain a good baseline. Next, the sample is irradiated with infrared light to obtain the IR spectrum. The reaction rate can be obtained by measuring the peak height of the methyl group (around 2,930 cm⁻¹) and the epoxy group (around 914 cm⁻¹) in the IR spectrum, and then calculating the ratio of the peak height of the epoxy group to the peak height of the methyl group before and after the reaction (before and after laser irradiation), as shown in the following formula.

$$reaction rate ( \% ) = \{ 1 - ( a / b ) / ( A / B ) \} \times 100$$

In the above formula, A is the peak height of the epoxy group before the reaction, B is the peak height of the methyl group before the reaction, a is the peak height of the epoxy group after the reaction, and b is the peak height of the methyl group after the reaction. In the case where another peak overlaps with the epoxy group peak, the peak height of the sample that has been fully cured (reaction rate 100%) can be considered as 0%.

In the case of a curable resin film that uses the reaction of (meth)acrylate compounds, as with the case of the epoxy compound, for example, the reaction rate can be obtained by measuring the peak height of the methyl group (around 2,930 cm⁻¹) and (meth)acryloyl group (around 1,635 cm⁻¹) in the infrared absorption spectrum, and then calculating the ratio of the peak height of the (meth)acryloyl group to the peak height of the methyl group before and after the reaction.

If the peak height of the (meth)acryloyl group is small, or if the sample contains alicyclic epoxy or oxetanyl groups, the reaction rate can be determined by preparing a sample as follows and using high-performance liquid chromatography (HPLC), for example. First, a cured individualized piece is sampled using a pen-type cutter with a sharp tip. Next, after collecting a sample weighing at least 0.015 mg, it is placed in a vial and the extraction solvent, acetonitrile, is added. The extraction solvent volume is calculated by determining an arbitrary concentration in the range of 0.025 to 0.25%. Then, the vial is set in the main body of the measuring device to measure HPLC under the following measurement conditions, for example.
Extraction: ACN 0.025 to 0.25%
Instrument: UPLC (manufactured by Waters)
Gradient conditions: A60B40 (hold for 1 min) then A1B99 (hold for 6 min) after 5 min
*A is water/acetonitrile=9:1, B is acetonitrile
   Flow rate: 0.4 mL/min
   Column: 10 cm
   Measurement temperature: 40° C.
   Injection volume: 5 μL

From the chromatogram obtained by HPLC, the reaction rate of the individualized piece can be calculated using the following formula based on the decay rate of the reactive component before and after the reaction (before and after laser irradiation).

$$reaction rate ( \% ) = \{ 1 - c / C \} \times 100$$

In the above formula, C is the peak height or area of the reactive component before the reaction, and c is the peak height or area of the reactive component after the reaction.

### Implementation 1

The method for manufacturing an individualized-piece-film shown as Implementation 1 uses a mask having a rectangular window of the opening to peel off unnecessary portions of the anisotropic conductive film from the base material, thereby forming a rectangular individualized piece with the remaining portions of the anisotropic conductive film.

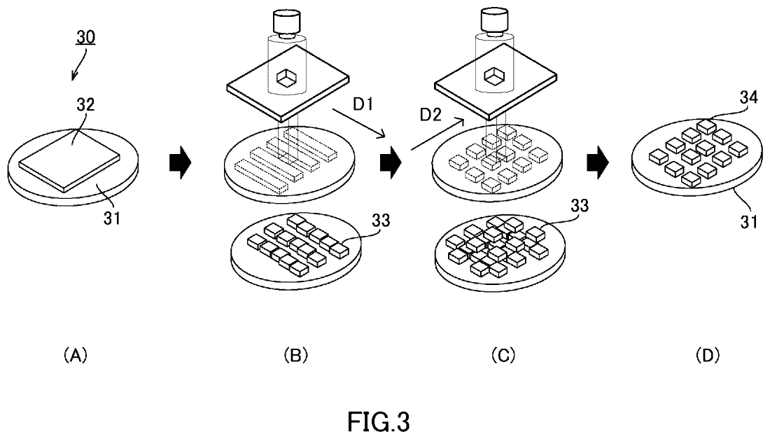

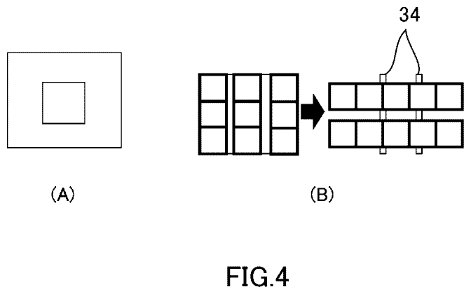

FIG. 3 is a view used to explain an example of a method for manufacturing an individualized-piece-film, which is shown as Implementation 1, in which FIG. 3 (A) shows an anisotropic conductive film substrate on which an anisotropic conductive film is formed on a base material, FIG. 3 (B) shows the removal portion being peeled off in the first direction, FIG. 3 (C) shows the removal portion being peeled off in the second direction, and FIG. 3 (D) shows the individualized-piece-film on which individualized pieces of the anisotropic conductive film are formed on a base material. FIG. 4 (A) is a schematic view of an example of a mask having a rectangular window of the opening, and FIG. 4 (B) is a schematic view of an example of the irradiation of laser light that has passed through the opening of the mask. In FIGS. 3 and 4, the mask opening is shown as a single opening, but it is preferable for there to be a plurality of openings arranged at a predetermined pitch.

First, as shown in FIG. 3 (A), an anisotropic conductive film substrate 30 is prepared, with an anisotropic conductive film 32 formed on a base material 31. Next, as shown in FIGS. 3 (B) and 4 (B), the anisotropic conductive film substrate 30 is turned over, and laser light is irradiated from the base material 31 side, so that the rectangular-shaped removal portion 33 of the anisotropic conductive film 32 is peeled off by the laser light that passes through the rectangular window of the opening of the mask. Then, as shown in FIG. 4 (B), the range of the rectangular removal portion 33 is moved in the first direction D1 to form an anisotropic conductive film with the first direction D1 of the mask as the longitudinal direction and the second direction D2, which is perpendicular to the first direction D1, as the transverse direction.

Next, as shown in FIGS. 3 (C) and 4 (B), the range of the rectangular removal portion 33 is moved in the second direction D2 with respect to the anisotropic conductive film with the first direction D1 as the longitudinal direction and the second direction D2, which is orthogonal to the first direction D1, as the transverse direction. This can form a rectangular individualized piece 34 with a predetermined width in the first direction D1 and a predetermined width in the second direction D2, as shown in FIG. 3 (D).

When moving the range of the rectangular removal portion 33 in the first or second direction, it is preferable to overlap the range of the rectangular removal portion 33. This suppresses burrs from forming during the individualization process and suppresses curling or chipping during the individualized piece transfer step.

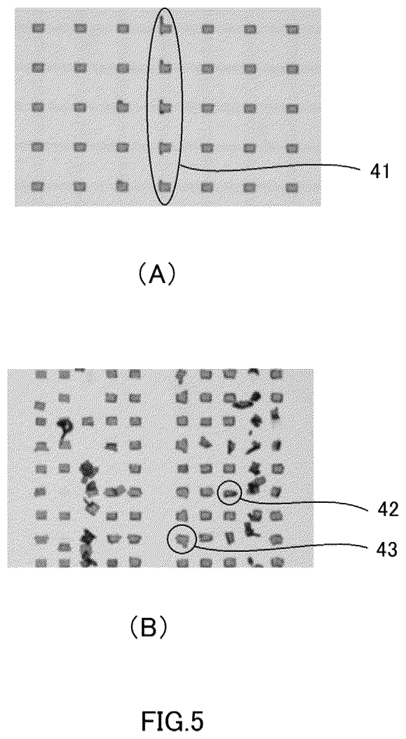

FIG. 5 (A) is a microscope photograph showing an example of a piece that has burrs formed during an individualization process, and FIG. 5 (B) is a microscope photograph showing an example of a piece that has curling or chipping formed during the transfer of the individualized pieces. In the case of moving the range of the removal portion, if the overlap of the range of the removal portion is insufficient, individualized pieces 41 may be formed in which burrs occur at the interface between adjacent ranges of the removal portion as shown in FIG. 5 (A). The individualized pieces 41 in which burrs occur become difficult to transfer to the correct position, and as shown in FIG. 5 (B), they become individualized pieces 42 in which curling occurs or individualized pieces 43 in which chipping occurs, so that transfer success rate decreases.

### Implementation 2

The method for manufacturing an individualized-piece-film shown as Implementation 2 uses a mask having a light-shielding portion of a predetermined shape formed in the window of the opening to peel off unnecessary portions of the anisotropic conductive film around the individualized-piece-film from the base material, thereby forming individualized pieces of a predetermined shape with the remaining portions of the anisotropic conductive film.

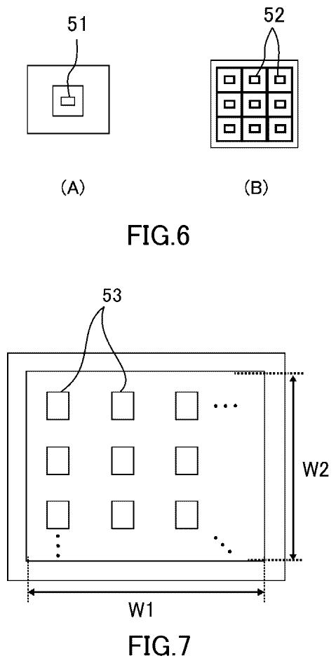

FIG. 6 (A) is a schematic diagram showing an example of a mask with a light-shielding portion in the window of the opening, and FIG. 6 (B) is a schematic diagram showing an example of laser light irradiation passing through the opening of the mask. In FIGS. 6 (A) and 6 (B), there is one opening in the mask, but it is preferable to have multiple openings arranged at a predetermined pitch.

First, as in Implementation 1, an anisotropic conductive film substrate with an anisotropic conductive film formed on the base material is prepared, the anisotropic conductive film substrate is turned over, and laser light is irradiated from the base material side to peel off the removal portion of the anisotropic conductive film by the laser light that passes through the opening of the mask. As shown in FIG. 6 (A), the opening of the mask has a rectangular light-shielding portion 51 in the center of the rectangular window, so the removal portion has a donut shape with a rectangular hole at the center of the rectangle. Then, as shown in FIG. 6 (B), the range of the rectangular removal portion is moved in the first direction and the second direction, which is perpendicular to the first direction, to form rectangular individualized pieces 52 with a predetermined width in the first direction and a predetermined width in the second direction.

The method for manufacturing individualized-piece-film shown as Implementation 2 that includes a light-shielding portion 51 for forming individualized pieces 52 within the window of the opening of the mask can reliably remove the anisotropic conductive film around the individualized pieces 52. This prevents burrs from forming during the individualization process and suppresses curling and chipping during the individualized piece transfer step.

FIG. 7 is a schematic view of an example of a mask having multiple light-shielding portions within the window of the opening. In the aforementioned FIGS. 6 (A) and 6 (B), there is one light-shielding portion within the window of the opening of the mask, but, e.g., as shown in FIG. 7, there may be multiple light-shielding portions 53 formed within the window of the opening at a predetermined pitch in the X-axis direction and at a predetermined pitch in the Y-axis direction. The size of the window (W1×W2) can be determined based on the size of the mask and the maximum value of the effective range of the irradiation of laser light. By using such a mask, it is possible to form multiple individualized pieces with a single irradiation of laser light.

### Example of Opening Shape

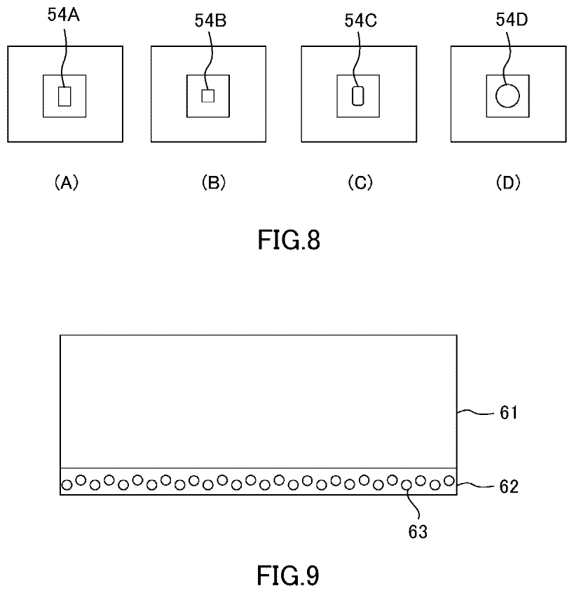

FIG. 8 is a schematic diagram showing examples of the shape of the opening of the mask, where FIG. 8 (A) shows a mask having a rectangular light-shielding portion within the window of the opening, FIG. 8 (B) shows a mask having a square light-shielding portion within the window of the opening, FIG. 8 (C) shows a mask having a rectangular light-shielding portion with rounded corners within the window of the opening, and FIG. 8 (D) shows a mask having a circular light-shielding portion within the window of the opening.

The opening of the mask may have a rectangular light-shielding portion 54A within the window of the opening, as shown in FIG. 8 (A), a square light-shielding portion 54B, as shown in FIG. 8 (B), a rectangular light-shielding portion 54C with rounded corners, as shown in FIG. 8 (C), or a circular light-shielding portion 54D, as shown in FIG. 8 (D). This makes it possible to obtain individualized pieces with rectangular, square, rounded rectangular, or circular shapes that are projected from the shape of the light-shielding portion. From the perspective of the workability of the individualized pieces and the transferability with LLO, the light-shielding portion is preferably a polygon with obtuse angles (angles greater than 90° and less than) 180°, a polygon with rounded corners, an ellipse, an oval, or a circle. If the light-shielding portion has sharp corners, the workability of the individualized pieces will deteriorate, and the frequency of individualized pieces curling or chipping during the transfer by LLO will increase.

### 2. Individualized-Piece-Film

The individualized-piece-film of this embodiment can be obtained by the method for manufacturing an individualized-piece-film described above. In other words, the individualized-piece-film includes a base material and individualized pieces of a predetermined shape composed of an anisotropic conductive film. Here, the thickness of the anisotropic conductive film, the melt viscosity of the anisotropic conductive film at 30° C., and the presence ratio of conductive particles with respect to the reference value is within the ranges described above.

As mentioned above, the shape of the individualized pieces is preferably at least one of a polygon with obtuse angles, a polygon with rounded corners, an ellipse, an oval, or a circle, in order to prevent curling or chipping when transferring the individualized pieces using LLO. As mentioned above, the base material can be any material that is transparent to laser light, and quartz glass, which has a high light transmissivity across the entire wavelength range, is particularly preferable.

The dimensions (vertical dimension×horizontal dimension) of each individualized piece are set appropriately according to the dimensions of the electronic component to be connected, and there are no particular restrictions on the ratio of the area of the individualized pieces to the area of the electronic component. If the size is too large, the film that does not participate in the connection will become relatively large, and there is a concern that this will affect the optical characteristics of the structure; therefore, the upper limit for the ratio of the area of the individualized piece to the area of the electronic component is 5.0 or less, preferably 4.0 or less, more preferably 3.2 or less, and even more preferably 2.4 or less. In addition, if the size becomes too small, the allowable range of the landing accuracy of the micro-LED will become narrower, and there is a concern that productivity will deteriorate; therefore, the lower limit of the ratio of the area of the individualized piece to the area of the electronic component is 0.5 or more, preferably 0.8 or more, and even more preferably 1.2 or more. These ratios can be designed as appropriate for the purpose of the structure. In addition, as with the thickness of the anisotropic conductive film, the thickness of the individualized pieces is preferably 1 μm or more and 10 μm or less, preferably 1 μm or more and 6 μm or less, and even more preferably 2 μm or more and 4 μm or less. The thickness of the individualized pieces can be measured using a known micrometer, digital thickness gauge, laser displacement meter, and the like, and for example, by measuring at ten or more locations and calculating the average. It is preferable that all the dimensions of the individualized pieces are the same, but in order to increase the design flexibility of the connection structure, there may be multiple types.

In addition, the distance between the individualized pieces on the base material is preferably 3 μm or more, more preferably 5 μm or more, and even more preferably 10 μm or more. The upper limit of the distance between the individualized pieces is preferably 3,000 μm or less, more preferably 1,000 μm or less, and even more preferably 500 μm or less. If the distance between the individualized pieces is too small, it will be difficult to transfer the individualized pieces, and if the distance between the individualized pieces is too large, it will be preferable to paste the individualized pieces. The distance between the individualized pieces can be measured using a microscope (optical microscope, metal microscope, and electron microscope, among others).

### 3. Method for Manufacturing Display Device

The method for manufacturing a display device in this embodiment includes: a formation step of irradiating an anisotropic conductive film formed on a base material with laser light from the base material side to remove the anisotropic conductive film in the irradiated area, thereby forming individualized pieces of a predetermined shape composed of the anisotropic conductive film on the base material; a transfer step of transferring the individualized pieces of the predetermined shape to a predetermined position on a wiring substrate or to an electrode surface of a light-emitting element; and a mounting step of mounting the light-emitting element to the wiring substrate via the transferred individualized piece. This makes it possible to obtain excellent workability of the individualized pieces and to reduce the tact time.

The shape of the individualized pieces is formed in correspondence with the shape of the electrodes of the wiring substrate and the light-emitting elements, and as mentioned above, in order to control the workability of the individualized pieces and to suppress the occurrence of curling or chipping when transferring the individualized pieces using LLO, the shape is preferably at least one selected from a polygon with obtuse angles, a polygon with rounded corners, an ellipse, an oval, and a circle.

The individualized pieces may be arranged in units of one pixel (e.g., one pixel of an RGB set), i.e., in units of multiple light-emitting elements, or they may be arranged in units of subpixels that constitute one pixel (e.g., any RGB unit), i.e., in units of a light-emitting element. This allows compatibility with both light-emitting element arrays with high PPI (pixels per inch) and light-emitting element arrays with low PPI. In addition, when RGB is composed as a single pixel, for example, three subpixels are arranged as a set, or a total of six subpixels, including three subpixels of redundant RGB circuitry, are arranged as a set, so the individualized pieces may be arranged in units of six subpixels.

The individualized pieces may also be arranged in units of electrodes corresponding to the first conductivity-type electrode on the p-side or the second conductivity-type electrode on the n-side of the light-emitting element, for example. Further, in order to improve productivity, the individualized pieces may also be arranged in a range that will not compromise transparency, such as in units of 1 mm×1 mm, for example.

In the formation step, the anisotropic conductive film may be pre-treated in order to efficiently remove unnecessary portions of the anisotropic conductive film. Examples of the pre-treatment may include cutting of individualized piece shapes in units of light-emitting elements or electrodes, and grid-shaped cutting made by intersecting multiple vertical cuts and multiple horizontal cuts. The cuts can be made using mechanical, chemical, or laser methods. The cuts do not need to be deep enough to reach the base material and can be half-cuts. This helps to suppress individualized pieces from peeling off.

There are no particular restrictions on the method of transferring individualized pieces in the transfer step, but examples may include the method of directly transferring and arranging individualized pieces from the base material to the wiring substrate or light-emitting element using the laser lift-off method (LLO method) described above, or the method of transferring and arranging individualized pieces from the transfer material to the wiring substrate or light-emitting element using transfer material (stamp material) to which individualized pieces have adhered in advance.

In addition, there are no particular restrictions on the method of arranging light-emitting elements in the mounting step, but the method may include the method of arranging light-emitting elements on a wiring substrate using the laser lift-off method (LLO method) described above, or the method of arranging light-emitting elements on a wiring substrate using a transfer material (stamp material) to which light-emitting elements have adhered in advance.

### First Embodiment

The method for manufacturing a display device according to the first embodiment includes: a formation step (A1) of removing an anisotropic conductive film in the area irradiated by laser light using a laser lift-off device to form individualized pieces of a predetermined shape composed of the anisotropic conductive film on a base material; a transfer step (B1) of transferring the individualized pieces of the predetermined shape to predetermined positions on a wiring substrate using the laser lift-off device; and a mounting step (C1) of arranging the light-emitting elements in predetermined positions on the wiring substrate to mount the light-emitting elements on the wiring substrate using the laser lift-off device.

In the following, the formation step (A1) of forming individualized pieces of a predetermined shape, the transfer step (B1) of transferring the individualized pieces of the predetermined shape, and the mounting step (C1) of mounting the light-emitting element to the wiring substrate will be described with reference to FIGS. 9 to 12.

### Formation Step (A1)

In the formation step (A1), an anisotropic conductive film is prepared on a base material, and using the laser lift-off device described above, laser light is irradiated from the base material side, and the removal portion of the anisotropic conductive film is peeled off by the laser light that passes through the opening of the mask described above to form individualized pieces. The method of forming individualized pieces is the same as the method for manufacturing an individualized-piece-film described above, so a detailed explanation is omitted here.

FIG. 9 is a cross-sectional view schematically illustrating the anisotropic conductive film provided on the base material. As shown in FIG. 9, the anisotropic conductive film substrate includes a base material 61 and an anisotropic conductive film containing conductive particles 63, and the anisotropic conductive film 62 is provided on the base material 61. The base material 61 and the anisotropic conductive film 62 are the same as the base material 31 and the anisotropic conductive film 32 described above, so the description thereof is omitted here.

Also, from the perspective of improving ablation resistance, it is preferable that the conductive particles 63 include metals with a melting point of 1,400° C. or higher. From the perspective of availability, it is preferable that the upper limit of the melting point of the metal is around 3,500° C. Also, from the perspective of availability, the metal that constitutes the conductive particles 63 is preferably to include nickel, palladium, or ruthenium.

Also, when using, the metal-coated resin particles formed by coating the surface of resin particles with a metal or the metal-coated inorganic particles formed by coating the surface of inorganic particles with a metal as the conductive particle 63, in order to minimize the effect of ablation on the resin particles or inorganic particles, it is preferable to make the thickness of the metal coating 0.08 μm or more, more preferably 0.1 μm or more, particularly preferably 0.15 μm or more, and most preferably 0.2 μm or more. The upper limit of this metal coating thickness depends on the diameter of the conductive particle 63, but it is preferable to be 20% of the diameter of the conductive particle 63 or about 0.5 μm.

### Transfer Step (B)

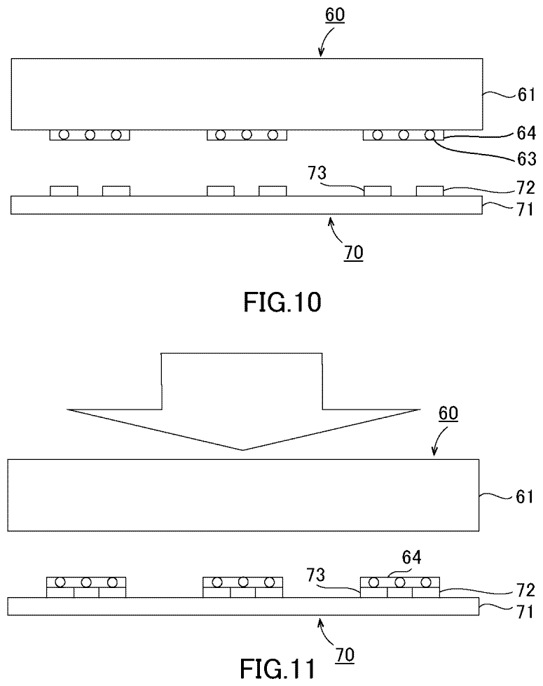

FIG. 10 is a cross-sectional view schematically illustrating a state in which an individualized-piece-film and a wiring substrate face each other. As shown in FIG. 10, in the transfer step (B), the individualized-piece-film 60 and the wiring substrate 70 are brought face to face.

The individualized-piece-film 60 includes the base material 61 and the individualized pieces 64 constituted by an anisotropic conductive film containing conductive particles 63, and the individualized pieces 64 are arranged on the surface of the base material 61 in units of light-emitting elements. The base material 61 is preferably one that is transparent to laser light, and a quartz glass plate, which has a high light transmissivity across the entire wavelength range, is particularly preferable.

The dimensions (vertical dimension×horizontal dimension) of the individualized pieces 64 are set appropriately according to the dimensions of the light-emitting elements, which are chip components, and the ratio of the area of the individualized pieces 64 to the area of the light-emitting elements is preferably 0.5 to 5.0, more preferably 0.5 to 4.0, and even more preferably 0.5 to 2.0. In addition, the thickness of the individualized pieces 64 is preferably 2 to 10 μm, more preferably 3 to 8 μm or less, and even more preferably 4 to 6 μm or less. It is preferable that all the dimensions of the individualized pieces are the same, but in order to increase the design flexibility of the connection structure, there may be multiple types. The individualized piece 64 may be provided only on the electrodes, and in this case, they may be interpreted as a conductive film. This makes it possible to obtain a connection structure with excellent light transmissive properties, conductive properties, and insulating properties that could not be achieved with conventional connections using ACP (anisotropic conductive paste), ACF (anisotropic conductive film), NCF (non-conductive film), and adhesives, among others.

In addition, the distance between the individualized pieces arranged on the base material 61 is preferably 3 μm or more, more preferably 5 μm or more, and even more preferably 10 μm or more. The upper limit of the distance between the individualized pieces is preferably 3,000 μm or less, more preferably 1,000 μm or less, and even more preferably 500 μm or less. If the distance between individualized pieces is too small, it will be difficult to obtain excellent light transmissivity and appearance, and if the distance between individualized pieces is too large, it will be difficult to obtain a display device with a high PPI. The distance between the individualized pieces can be measured using a microscope (optical microscope, metal microscope, and electron microscope, among others).

The wiring substrate 70 has a first conductivity-type circuit pattern and a second conductivity-type circuit pattern on the base material 71, and has a first electrode 72 and a second electrode 73 in positions corresponding to a first conductivity-type electrode on the p side and a second conductivity-type electrode on the n side, respectively, so that the light-emitting elements are arranged in units of subpixels (sub-pixels) that constitute one pixel. The wiring substrate 70 forms circuit patterns such as data lines and address lines of the matrix wiring, and enables the light-emitting elements corresponding to each subpixel that constitutes one pixel to be turned on and off. A single pixel may be composed of three subpixels, e.g., R (red), G (green), B (blue), four subpixels, e.g., RGBW (white), RGBY (yellow), or two subpixels, e.g., RG, GB.

In addition, when the wiring substrate 70 is used for transparent display applications, it is preferable to be a transparent substrate, and the base material 71 is preferably glass or PET (polyethylene terephthalate). The first electrode 72 and the second electrode 73 are preferably transparent conductive films such as ITO (Indium-Tin-Oxide), IZO (Indium-Zinc-Oxide), ZnO (Zinc-Oxide), and IGZO (Indium-Gallium-Zinc-Oxide).

FIG. 11 is a cross-sectional view schematically illustrating a state in which the individualized pieces of the anisotropic conductive film are transferred to and arranged in predetermined positions on the wiring substrate by irradiating laser light from the base material side. As shown in FIG. 11, in the transfer step (B), the laser lift-off device described above is used to irradiate laser light from the base material 61 side and transfer and arrange the individualized pieces 64 of the anisotropic conductive film to/in predetermined positions on the wiring substrate 70. By aligning the base material 61 and the substrate 70 and transferring the material, it is possible to arrange the individualized pieces 64 on the substrate 70 in units of subpixels.

If the size of the base material 61 is larger than the size of the substrate 70, the individualized pieces 64 can be arranged in the screen region of the substrate 70 in units of subpixels by aligning the base material 61 and transferring the individualized pieces 64 multiple times.

The laser lift-off device described above can be used to transfer the individualized pieces 64 of the anisotropic conductive film. This transfer method is called laser lift-off, and for example, it is a method that uses laser ablation. In the laser lift-off device described above, the individualized-piece-film 60, which is the donor substrate, is held on the donor stage, and the wiring substrate 70, which is the receptor substrate, is held on the receptor stage. The distance between the individualized-piece-film and the wiring substrate is preferably 10 to 20,000 μm, more preferably 50 to 1,500 μm, and even more preferably 80 to 1,000 μm.

As a laser device, e.g., an excimer laser that oscillates laser light with a wavelength of 180 nm to 360 nm can be used. The oscillation wavelengths of excimer lasers are, e.g., 193, 248, 308, and 351 nm, and an appropriate oscillation wavelength can be selected from these according to the light absorption properties of the material of the anisotropic conductive film.

The mask uses a pattern with an array of windows of a predetermined size and pitch so that the projection at the interface between the base material 61 and the individualized pieces 64 of the anisotropic conductive film forms the desired arrangement of laser light. The mask has a pattern applied to the base material 61 using chrome plating, e.g., the window areas that are not chrome-plated pass through laser light, while the chrome-plated areas block laser light.

The incident light from the laser device enters the telescope optics and is transmitted to the laser scanner 11. The laser light just before entering the laser scanner 11 is adjusted by the telescope optics so that it becomes roughly parallel light at any position within the movement range of the X-axis and Y-axis of the donor stage, and it enters the laser scanner 11 at roughly the same size and the same angle (perpendicular).

The laser light that passes through the laser scanner 11 passes through the field lens and enters the mask 12, and the laser light that passes through the pattern of the mask 12 enters the projection lens 13. The laser light emitted from the projection lens 13 enters from the base material 61 side and is accurately projected onto the position of the individualized piece 64 of the anisotropic conductive film formed on a surface (bottom surface) of the base material at a reduced size of the mask pattern.

The pulse energy of the laser light that is irradiated to and imaged at the interface between the individualized piece of the anisotropic conductive film and the base material is preferably 0.001 to 2 J, more preferably 0.01 to 1.5 J, and even more preferably 0.1 to 1 J. The fluence is preferably 0.001 to 2 J/cm², more preferably 0.01 to 1 J/cm², and even more preferably 0.05 to 0.5 J/cm². The pulse width (irradiation time) is preferably 0.01 to 1×10⁹ picoseconds, more preferably 0.1 to 1×10⁷ picoseconds, and even more preferably 1 to 1×10⁵ picoseconds. The pulse frequency is preferably 0.1 to 10,000 Hz, more preferably 1 to 1,000 Hz, and even more preferably 1 to 100 Hz. The number of irradiation pulses is preferably between 1 and 30,000,000.

Such a laser lift-off device can generate an impact wave in the individualized piece 64 that has been irradiated with laser light at the interface between the base material 61 and the individualized piece 64 of the anisotropic conductive film, lift the individualized piece 64 away from the base material 61 and towards the wiring substrate 70, and cause multiple individualized pieces 64 to land at predetermined positions on the wiring substrate 70. This makes it possible to transfer and arrange the individualized pieces 64 of the anisotropic conductive film to/on the wiring substrate 70 with high accuracy and efficiency to reduce the tact time.

The reaction rate of the individualized pieces 64 of the anisotropic conductive film after the transfer step (B1) is preferably 25% or less, more preferably 20% or less, and even more preferably 15% or less. The reaction rate of the individualized pieces 64 after the transfer step (B1) being 25% or less makes it possible to thermocompression-bond the light-emitting elements in the mounting step (C1). As mentioned above, the reaction rate can be measured using, e.g., FT-IR.

In addition, as with the distance between the individualized pieces arranged on the base material 61 of the individualized-piece-film 60, the distance between the individualized pieces arranged in the predetermined position on the wiring substrate 70 is preferably 3 μm or more, more preferably 5 μm or more, and even more preferably 10 μm or more. The upper limit of the distance between the individualized pieces is preferably 3,000 μm or less, more preferably 1,000 μm or less, and even more preferably 500 μm or less. If the distance between the individualized pieces is too small, it will be preferable to paste the anisotropic conductive film to the entire surface of the wiring substrate 70, and if the distance between the individualized pieces is too large, it will be preferable to paste the anisotropic conductive film to the predetermined position of the wiring substrate 70. The distance between the individualized pieces can be measured using a microscope (optical microscope, metal microscope, and electron microscope, among others).

### Mounting Step (C1)

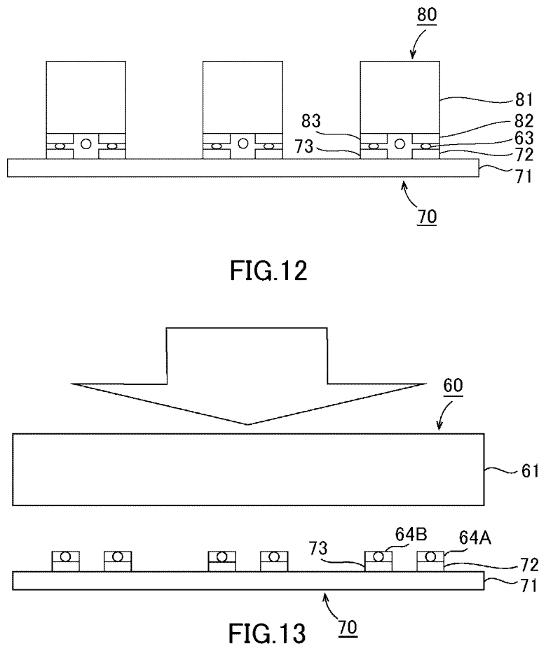

FIG. 12 is a cross-sectional view schematically illustrating a state in which light-emitting elements are mounted on the individualized pieces arranged in predetermined positions on the wiring substrate. As shown in FIG. 12, in the mounting step (C1), the light-emitting element 80 is mounted on the individualized piece 64 arranged in the predetermined position on the wiring substrate 70.

The light-emitting element 80 has a main body 81, a first conductivity-type electrode 82, and a second conductivity-type electrode 83, and has a horizontal structure in which the first conductivity-type electrode 82 and the second conductivity-type electrode 83 are arranged on the same side. The main body 81 has a so-called double heterostructure, including a first conductivity-type cladding layer made of, e.g., n-GaN, an active layer made of, e.g., InₓAl_{y}Ga_{1-x-y}N layers, and a second conductivity-type cladding layer made of, e.g., p-GaN. The first conductivity-type electrode 82 is formed in part of the first conductivity-type cladding layer by a passivation layer, and the second conductivity-type electrode 83 is formed in part of the second conductivity-type cladding layer. When a voltage is applied between the first conductivity-type electrode 82 and the second conductivity-type electrode 83, carriers are concentrated in the active layer and recombined, resulting in light emission.

The light-emitting elements 80 are arranged on the substrate 70 in correspondence with each subpixel that constitutes a single pixel, to form a light-emitting element array. A single pixel may be composed of three subpixels, e.g., R (red), G (green), B (blue), four subpixels, e.g., RGBW (white), RGBY (yellow), or two subpixels, e.g., RG, GB.

Examples of the arrangement of subpixels may include, in the case of RGB, stripe arrangement, mosaic arrangement, and delta arrangement, among others. The stripe arrangement is one in which RGB is arranged in a vertical stripe pattern, and this arrangement can achieve high resolution. In addition, the mosaic arrangement is one in which the same color of RGB is arranged diagonally, and a more natural image can be achieved than with the stripe arrangement. In addition, the delta arrangement is one in which RGB is arranged in a triangular pattern, and each dot is offset by half a pitch for each field, and a natural image display can be achieved.

In the mounting step (C1), the light-emitting element 80 can be placed in the predetermined position on the wiring substrate 70 using the laser lift-off device described above. In the aforementioned laser lift-off device, the light-emitting element, which is the donor substrate, is held on the donor stage, and the wiring substrate 70, which is the receptor substrate, is held on the receptor stage. The distance between the light-emitting element and the wiring substrate is preferably 10 to 1,000 μm, more preferably 50 to 500 μm, and even more preferably 80 to 200 μm.

As a method for connecting the light-emitting element 80 to the wiring substrate 70, a connection method such as thermocompression bonding, photocompression bonding, or thermophotocompression bonding, which is used in a known anisotropic conductive film, can be selected and used as appropriate. In the case where the conductive particles are solder particles, they may be connected by reflow. The conditions for thermocompression bonding are, e.g., a temperature of 150° C. to 260° C., a pressure of 1 MPa to 60 MPa, and a time of 5 seconds to 300 seconds. By curing the anisotropic conductive film, a cured film is formed, and the light-emitting elements 80 can be anisotropically connected on the wiring substrate 70 in a state where the wiring substrate 70 is exposed without the presence of the cured film between the light-emitting elements 80. In addition, by making the wiring substrate 70 a transparent substrate, superior light transmissive properties can be obtained compared to when the entire surface of the wiring substrate 70 is covered with the anisotropic conductive film.

### Modification of First Embodiment

In the transfer step (B1) of the first embodiment described above, as shown in FIGS. 10 and 11, the individualized pieces 64 of the anisotropic conductive film are arranged on the wiring substrate 70 in units of subpixels, which are units of light-emitting elements, but the arrangement is not limited to this, and for example, they may be arranged in units of electrodes corresponding to the first conductivity-type electrode on the p side or the second conductivity-type electrode on the n side of the light-emitting element.

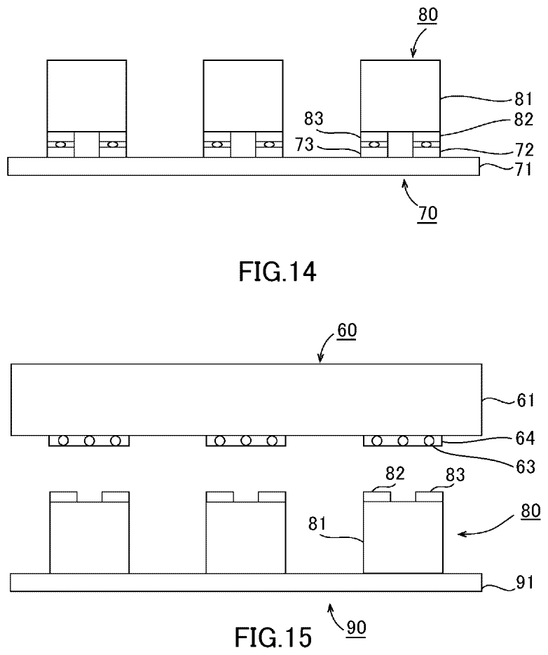

FIG. 13 is a cross-sectional view schematically illustrating a state in which the individualized pieces of the anisotropic conductive film are transferred to and arranged in the electrode position of the wiring substrate by irradiating laser light from the base material side, and FIG. 14 is a cross-sectional view schematically illustrating a state in which light-emitting elements are mounted on the individualized pieces arranged on the wiring substrate in units of electrodes. As shown in FIG. 13, in the transfer step (B1), the first individualized piece 64A and the second individualized piece 64B are transferred to, e.g., the first electrode 72 and the second electrode 73 respectively corresponding to the first conductivity-type electrode 82 on the p-side and the second conductivity-type electrode 83 on the n-side of the light-emitting element 80.

The dimensions (vertical dimension×horizontal dimension) of the individualized pieces 64A, 64B are set appropriately according to the dimensions of the electrodes of the light-emitting element, and there are no particular restrictions on the ratio of the area of the individualized pieces to the area of the electronic component. If the ratio is too large, the film that does not participate in the connection becomes relatively large; therefore, the upper limit for the ratio of the area of the individualized pieces to the area of the electrode is 5.0 or less, preferably 4.0 or less, more preferably 3.2 or less, and even more preferably 2.4 or less. In addition, if the ratio is too small, there is a concern that the connection will become unstable; therefore the lower limit for the ratio of the area of the individualized piece to the area of the electronic component is 0.5 or more, preferably 0.8 or more, and even more preferably 1.2 or more. These ratios can be designed as appropriate for the purpose of the structure. In addition, the thickness of the individualized pieces is preferably 2 to 10 μm, more preferably 3 to 8 μm, and even more preferably 4 to 6 μm or less.

As shown in FIG. 14, in the mounting process (C1), the light-emitting elements 80 are mounted on the individualized pieces 64A, 64B, which are arranged in units of electrodes on the wiring substrate 70. This allows the transparency of the display device to be further improved.

As explained above, the method for manufacturing a display device in the first embodiment allows the individualized pieces 64 of the anisotropic conductive film to be transferred to and arranged on the wiring substrate 70 with high accuracy and efficiency by irradiating laser light, thereby reducing the tact time. In addition, it is possible to obtain excellent light transmissive properties, conductive properties, and insulating properties that could not be achieved with conventional connections using ACP, ACF, NCF, or adhesive, thereby enabling the production of high-luminance, high-definition transparent displays.

### Second Embodiment

The method for manufacturing a display device according to the second embodiment includes: a formation step (A2) of removing an anisotropic conductive film in the area irradiated by laser light using a laser lift-off device to form individualized pieces of a predetermined shape composed of the anisotropic conductive film on a base material; a transfer step (B2-1) of transferring the individualized pieces of the predetermined shape to the electrode surface of the light-emitting element using a laser lift-off device; retransfer step (B2-2) of retransferring the light-emitting elements to which the individualized pieces have been transferred to a predetermined position on the circuit board using a laser lift-off device; and a mounting step (C2) of mounting the light-emitting element on the wiring substrate. This makes it possible to obtain excellent workability and transferability of the individualized pieces and to reduce the tact time.

In the following, the formation step (A2) of forming individualized pieces of a predetermined shape, the transfer step (B2-1) of transferring the individualized pieces of the predetermined shape to the electrode surface of the light-emitting element, the retransfer step (B2-2) of retransferring the light-emitting element with the individualized piece to a predetermined position on the substrate, and the mounting step (C2) of mounting the light-emitting element on the substrate will be described with reference to FIGS. 15 to 17. The same symbols are used for the same components as in the first embodiment, and the description thereof is omitted.

### Formation Step (A2)

The formation step (A2) is the same as the formation step (A1) in the first embodiment, so the detailed description thereof is omitted here.

### Transfer Step (B2-1)

FIG. 15 is a cross-sectional view schematically illustrating a state in which individualized pieces of the anisotropic conductive film provided on the base material and light-emitting elements arranged on the transfer substrate face each other. As shown in FIG. 15, in the transfer step (B2), the individualized pieces 64 of the anisotropic conductive film provided on the base material 61 and the transfer substrate 90 are brought face to face. The individualized piece 64 is formed on the base material 61 in correspondence with the shape of the electrode of the light-emitting element 50.

The transfer substrate 90 includes a base material 91 and light-emitting elements 80 arranged on the base material 91. The base material 91 is selected appropriately according to the transfer method used in the retransfer step (B2-2) described later. For example, if the transfer method using laser ablation is used in the retransfer step (B2-2) described later, the base material 91 only needs to be transparent to laser light, and quartz glass, which has a high light transmissivity across the entire wavelength range, is particularly preferable. Furthermore, for example, in the retransfer step (B2-2) described later, when the transfer substrate 90 is pasted to the wiring substrate 20 to transfer the light-emitting element 80, the base material 91 may have a silicone rubber layer.

In the transfer step (B2-1), a transfer method using laser ablation, called laser lift-off, can be used in the same way as the first embodiment described above.

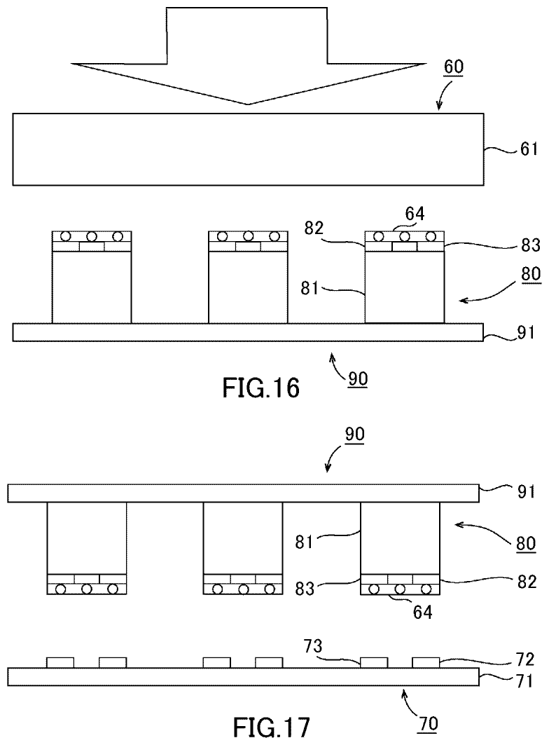

FIG. 16 is a cross-sectional view schematically illustrating a state in which individualized pieces of the anisotropic conductive film are transferred to light-emitting elements arranged on the transfer substrate by irradiating laser light from the base material side. As shown in FIG. 16, in the transfer step (B2-1), laser light is irradiated from the base material 61 side to transfer the individualized pieces 64 of the anisotropic conductive film onto the light-emitting elements 80 arranged on the transfer substrate 90.

As with the first embodiment described above, the laser lift-off device described above can be used to transfer the individualized pieces 64 of the anisotropic conductive film. Such a laser lift-off device can generate an impact wave in the individualized piece 64 that has been irradiated with laser light at the interface between the base material 61 and the individualized piece 64 of the anisotropic conductive film, lift the multiple individualized pieces 64 away from the base material 61 and towards the light-emitting element 80 arranged on the transfer substrate, and cause individualized pieces 64 to land on the light-emitting elements 80 with high accuracy.

### Retransfer Step (B2-2)

FIG. 17 is a cross-sectional view schematically illustrating a state in which light-emitting elements to which the individualized pieces have been transferred are retransferred to a wiring substrate. As shown in FIG. 17, in the retransfer step (B2-2), the light-emitting elements 80 to which the individualized pieces 64 have been transferred are retransferred onto the wiring substrate 70. There are no particular restrictions on the method of retransferring, but for example, the light-emitting element 80 to which the individualized pieces 64 have been transferred may be directly transferred from the transfer substrate 90 to the wiring substrate 70 and arranged on the wiring substrate 70 using the laser lift-off (LLO) method, or the light-emitting element 80 may be transferred to and arranged on the wiring substrate 70 from the transfer substrate 90 to which the light-emitting element 80 to which the individualized pieces 64 have been transferred is adhered in advance.

In the retransfer step (B2-2), it is preferable to transfer the light-emitting elements 80 in units of subpixels that constitute a single pixel. This allows compatibility with both light-emitting element arrays with high PPI (pixels per inch) and light-emitting element arrays with low PPI.

### Mounting Step (C2)

In the mounting step (C2), the light-emitting elements 80 arranged in predetermined positions on the wiring substrate 70 are mounted via the individualized pieces 64. The state of the light-emitting elements 80 mounted is the same as the first embodiment shown in FIG. 12. The connection method of the light-emitting elements 80 to the wiring substrate 70 is the same as the first embodiment. This allows the light-emitting elements 80 to be anisotropically connected on the wiring substrate 70 in a state where the wiring substrate 70 is exposed without the presence of the anisotropic conductive film between the light-emitting elements 80. In addition, by making the wiring substrate 70 a transparent substrate, superior light transmissive properties can be obtained compared to when the entire surface of the wiring substrate 70 is covered with the anisotropic conductive film.

### Modification of Second Embodiment

In the transfer step (B2-1) of the second embodiment described above, as shown in FIGS. 15 and 16, the individualized pieces 64 of the anisotropic conductive film are transferred onto the light-emitting element 80, but the transfer is not limited to this, and for example, the individualized pieces of the anisotropic conductive film may be transferred onto the light-emitting element in units of electrodes. In other words, as in the modification of the first embodiment shown in FIG. 14, the first individualized pieces and the second individualized pieces can be transferred and mounted on the first conductivity-type electrode 82 on the p-side and the second conductivity-type electrode 83 on the n-side of the light-emitting element 80, respectively. This allows the transparency of the display device to be further improved.

As explained above, the manufacturing method for the display device in the second embodiment allows the individualized pieces 64 of the anisotropic conductive film to be transferred and arranged on the light-emitting element 80 with high accuracy and efficiency through the irradiation of laser light, thereby reducing the tact time. In addition, it is possible to obtain excellent light transmissive properties, conductive properties, and insulation properties that could not be achieved with conventional connections using ACP, ACF, NCF, or adhesive provided on the entire surface, thereby enabling the production of high-luminance, high-definition transparent displays.

### Repair Step

In the display device according to the aforementioned embodiment, e.g., if there is a light-emitting element that is not lighting up, a repair step can be performed by removing the light-emitting element that is not lighting up using the aforementioned laser lift-off device, and then transferring an individualized piece of the anisotropic conductive film to the relevant portion and mounting the light-emitting element. In the laser lift-off device, a display device having a wiring substrate on which light-emitting elements are arranged is held on the donor stage, the desired light-emitting element and individualized piece are peeled off by irradiating laser light from the base material side, and the light-emitting element and individualized piece peeled off from the wiring substrate are received by the receptor substrate. In this embodiment, the wiring substrate is exposed between the individualized pieces, so it is preferable to perform repair on an individualized piece basis.

In addition, the aforementioned embodiment gave an example of a method for manufacturing a display device as a display, but the present technology is not limited to this, and can also be applied to a method for manufacturing a light-emitting device as a light source, for example. It can also be applied to a method for manufacturing a connection structure that connects a first electronic component and a second electronic component. That is, the method for manufacturing a connection structure includes: a formation step of irradiating a laser light from a base material side to an anisotropic conductive film formed on a base material to remove the anisotropic conductive film in the irradiated area, thereby forming an individualized piece of a predetermined shape composed of the anisotropic conductive film on the base material; a transfer step of transferring the individualized piece of the predetermined shape to a predetermined position of a first electronic component; and a mounting step of mounting a second electronic component to a predetermined position of the wiring substrate, wherein the thickness of the anisotropic conductive film is 0.9 times or more and 8 times or less of the particle diameter of the conductive particles in the anisotropic conductive film, and the melt viscosity of the anisotropic conductive film at 30° C. is 2,000 Pa*s or more and 800,000 Pa*s or less. Examples of the first and second electronic components include light-emitting devices, integrated circuits (ICs), flexible printed circuits (FPCs), liquid crystal display (LCD) panels, flat panel displays (FPDs) such as organic light-emitting diodes (OLEDs), transparent substrates for touch panels, and printed wiring boards (PWBs). The material of the printed wiring board is not particularly limited and can be, e.g., glass epoxy such as FR-4 base material, or plastic such as thermoplastic resin, or ceramic. In addition, the transparent substrate is not particularly limited as long as it is highly transparent and can be glass or plastic.

### 4. Display Device

The display device according to the present embodiment can be obtained by the method for manufacturing a display device described above. That is, the display device includes a plurality of light-emitting elements, a wiring substrate on which the light-emitting elements are arranged, and a cured film that connects the light-emitting elements and the wiring substrate, and the cured film is made by curing individualized pieces of a predetermined shape composed of the above-described anisotropic conductive film.

The shape of the individualized pieces is preferably at least one selected from a polygon with obtuse angles, a polygon with rounded corners, an ellipse, an oval, and a circle. This allows the substrate to be exposed between the individualized pieces and provides excellent light transmissive properties and a pleasing appearance.

As shown in the aforementioned FIGS. 12 and 14, the display device includes the plurality of light-emitting elements 80, the substrate 70 on which the light-emitting elements 80 are arranged, and the cured film that connects the plurality of light-emitting elements 80 to the substrate 70.

The cured film is a cured piece of the anisotropic conductive film of a predetermined shape. The arrangement of the individualized pieces on the substrate 70 is not particularly limited as long as a light transmissive property is achieved, but it is preferable that it is in units of subpixels corresponding to the light-emitting elements 80. By arranging the individualized pieces in units of subpixels, the exposed portions of the substrate between the individualized pieces can be increased, and an excellent light transmissive property can be achieved. When the individualized pieces are arranged in units of sub-pixels, the area of the individualized pieces that exist in the exposed area between the micro-LEDs is 3.2 times or less, preferably 2.4 times or less, and even more preferably 1.2 times or less the area of the micro-LEDs. In addition, multiple light-emitting elements 80 in close proximity in units of subpixels can be connected with a single individualized piece. This can reduce the mounting speed (increase the mounting efficiency), and also expand the range of acceptable specifications depending on the transparency and color tone of the base material side.

As with the anisotropic conductive film, in the cured film of the anisotropic conductive film, the conductive particles are preferably arranged in a surface direction. By arranging conductive particles in a surface direction, the particle areal density becomes uniform, and conductivity and insulation properties can be improved. An example of the state in which conductive particles are arranged in a surface direction is a planar lattice pattern that has one or more array axes on which the conductive particles are arranged in a predetermined direction at a predetermined pitch, including oblique lattices, hexagonal lattices, square lattices, rectangular lattices, and parallelepiped lattices. The state in which the conductive particles are arranged in a surface direction may also be said that the conductive particles are arranged in the plane view of the film. In addition, the arrangement of conductive particles in a surface direction may be random, and the planar lattice pattern may have multiple regions that differ from each other.

The particle areal density of the cured film of the anisotropic conductive film can be designed appropriately according to the electrode size of the light-emitting element 80, and the lower limit of the particle areal density can be set to 500 particles/mm² or more, 20,000 particles/mm² or more, 40,000 particles/mm² or more, or 50,000 particles/mm² or more, and the upper limit of the particle areal density can be set to 1,500,000 particles/mm² or less, 1,000,000 particles/mm² or less, 500,000 particles/mm² or less, or 100,000 particles/mm² or less. This allows for excellent conductivity and insulation even when the electrode size of the light-emitting element 80 is small.

The particle areal density of the cured film of the anisotropic conductive films is the density of the conductive particles when the film is formed during manufacturing. This is the same whether the measurement is of randomly arranged particles or of particles arranged in a pattern. When calculating the number density of particles from multiple individualized pieces, the particle areal density can be calculated from the area including the individualized pieces and the spaces minus the spaces between individualized pieces, and the number of particles. In some cases, it is not appropriate to express the individualized pieces in terms of the number density, and it may be more appropriate to express it in terms of the area occupied by the particles in a single individualized piece, or the particle diameter, the distance between the centers of the particles, and the number of particles.

The particle areal density of the cured film of the anisotropic conductive film is the density of the conductive particles when the film is formed during manufacturing. This is the same whether the measurement is of randomly arranged particles or of particles arranged in a pattern. When calculating the number density of particles from multiple individualized pieces, the particle areal density can be calculated from the area including the individualized pieces and the spaces minus the spaces between individualized pieces, and the number of particles. In some cases, it is not appropriate to express the individualized pieces in terms of the number density, and it may be more appropriate to express it in terms of the area occupied by the particles in a single individualized piece, or the particle diameter, the distance between the centers of the particles, and the number of particles.

The number of conductive particles per individualized piece can be designed appropriately according to the electrode size of the light-emitting element 80, and the lower limit is, e.g., 2 or more, preferably 4 or more, and more preferably 10 or more, and the upper limit is 6,000 or less, preferably 500 or less, and more preferably 100 or less.

The average transmittance of visible light after the individualized pieces are placed (provided) on the substrate is preferably 20% or more, more preferably 35% or more, and even more preferably 50% or more. This makes it possible to obtain a display device with excellent light transmissive properties and a good appearance. Even if the substrate is not transparent, the average transmittance can be obtained by attaching the individualized pieces to a plain glass plate or a transparent substrate for evaluation and using these as a reference (Ref). Providing the light-emitting elements will decrease the average transmittance of visible light. In a case where a light-emitting element is mounted, the measurement is taken when the light-emitting element is not lit. The average transmittance of visible light can be measured using a UV-visible spectrophotometer, for example.

The size of the individualized piece may be smaller than the size of the light-emitting element 80, as long as conductivity is achieved. In addition, the individualized pieces may be located so that they present not only directly below the light-emitting element but also in the peripheral edge portion, as long as the light transmissive property of the display device is achieved.

The amount of protrusion of the individualized pieces from the light-emitting element 80 is preferably less than 30 μm, more preferably less than 10 μm, and even more preferably less than 5 μm. In addition, if the individualized pieces do not protrude, the amount of protrusion may be zero or even negative. This allows for superior light transmittance compared to configuration examples of display devices with a cured film on the entire surface of the substrate. The amount of protrusion of the individualized pieces from the light-emitting element 80 is the maximum value of the distance between the peripheral edge portion of the light-emitting element 80 and the peripheral edge portion of the individualized piece.

According to the display device of this embodiment, having an exposed portion where the substrate 70 is exposed between the individualized pieces of the cured film, it is possible to obtain excellent light transmissive properties, conductive properties, and insulation properties that could not be achieved with conventional connections using ACP, ACF, NCF, or adhesive provided on the entire surface, thereby enabling the production of high-luminance, high-definition transparent displays.

The above-mentioned embodiment gave an example of a display device in which light-emitting elements 80 are arranged in units of subpixels, but the present technology is not limited to this, and can also be applied to a light-emitting device as a light source, for example. The light-emitting device includes a plurality of light-emitting elements, a substrate on which the light-emitting elements are arranged, and a cured film that connects the light-emitting elements to the substrate, and the cured film is composed of a plurality of individualized pieces and has an exposed portion in which the substrate is exposed between the individualized pieces. With such a light-emitting device, the available number of chips per wafer can be increased by making the light-emitting elements 80 smaller, which makes it possible to reduce the price, and it also has industrial advantages such as making the light-emitting device thinner and more energy efficient.

This technology can also be applied to a connection structure that connects a first electronic component and a second electronic component. That is, the connection structure includes a first electronic component; a second electronic component; and a cured film connecting the first electronic component and the second electronic component, wherein the cured film is made by curing individualized pieces of a predetermined shape composed of an anisotropic conductive film, the thickness of the anisotropic conductive film is 0.9 times or more and 8 times or less of the particle diameter of the conductive particles in the anisotropic conductive film, and the melt viscosity of the anisotropic conductive film at 30° C. is 2,000 Pa*s or more and 800,000 Pa*s or less.

### EXAMPLES

### 3. Examples

In the examples, the anisotropic conductive films with a predetermined thickness, predetermined particle arrangement, predetermined particle alignment, and predetermined melt viscosity were processed into individualized pieces, and the shapes of the individualized pieces were evaluated. In addition, lighting evaluation was performed for the mounting body in which the μLED element was mounted using the processed individualized pieces. It should be noted that the present technology is not limited to these examples.

### Measurement of Melt Viscosity of Anisotropic Conductive Film

The melt viscosity of the anisotropic conductive film was measured at 30° C. using a rheometer (HAAKE MARS, manufactured by Thermo Fisher Scientific) under the following measurement conditions. Samples with a thickness of 300 μm made by laminating anisotropic conductive films were measured.
Measurement conditions: glass-coated polypropylene container (PP08, φ8 mm), frequency of 10 Hz

### Calculation of Presence Rate of Conductive Particles Relative to Reference Line

The cross-section of the anisotropic conductive film was observed under a microscope, and the average of the center positions of the conductive particles in the thickness direction in the predetermined range, where there were 200 or more conductive particles, was taken as the reference line; then, in the predetermined range, the percentage of conductive particles having a part of the outer diameter crossing the reference line was calculated.

### Individualization Process of Anisotropic Conductive Film

Using a laser lift-off device (LUM-XTR manufactured by Shin-Etsu Engineering), laser light was irradiated from the quartz glass side of the anisotropic conductive film attached to a 4-inch quartz glass to transfer the unnecessary part to the plain glass plate, thereby forming individualized pieces of the anisotropic conductive film on the quartz glass plate. As shown in the above-mentioned FIG. 2, an example of the laser lift-off device includes: a laser scanner that scans the optical axis of the laser light; a mask having multiple openings of a predetermined shape arranged at a predetermined pitch; a projection lens that reduces and projects the laser light onto the donor substrate; a donor stage that holds the donor substrate; and a receptor stage that holds the receptor substrate, and an anisotropic conductive film substrate, which is the donor substrate, is held on the donor stage, the plain glass plate, which is the receptor substrate, is held on the receptor stage, and the distance between the anisotropic conductive film and the plain glass plate is 100 μm.

An excimer laser with an oscillation wavelength of 248 nm was used for the laser device. The pulse energy of the laser light was 600 J, the fluence was 250 J/cm², the pulse width (irradiation time) was 30,000 picoseconds, the pulse frequency was 0.01 kHz, and the number of irradiation pulses was 1 pulse per individualized piece.

The pulse energy of the laser light irradiated at the interface between the anisotropic conductive film and the quartz glass plate was 0.001 to 2 J, the fluence was 0.001 to 2 J/cm², the pulse width (irradiation time) was 0.01 to 1×10⁹ picoseconds, the pulse frequency was 0.1 to 10,000 Hz, and the number of irradiation pulses was 1 to 30,000,000.

The mask had a pattern with a circular light-shielding portion formed to have the same shape as the individualized pieces, so that the projection at the interface between the anisotropic conductive film of the anisotropic conductive film substrate, which is the donor substrate, and the quartz glass plate would correspond to the arrangement of the size (a circle with a diameter of 80 μm) of the individualized piece with a pitch of 158 μm and 158 μm in both the horizontal and vertical directions. Laser light was irradiated through the mask, and anisotropic conductive films were punched out to form multiple circular individualized pieces with a diameter of 80 μm on the quartz glass.

### Evaluation of Shape of Individualized Pieces

After the anisotropic conductive films were processed into individualized pieces, 1,000 individualized pieces were selected at random from the total of 10,000 individualized pieces, and the individualized pieces with a non-defective shape (without any curling or chipping) were counted by visual inspection under a microscope (for details of the curling or chipping, see the individualized pieces 42, 43 in FIG. 5 (B) above). The non-defective rate of the shape was then calculated using the following formula. The shape non-defective rate is preferably 85% or more, more preferably 95% or more, and even more preferably 99% or more.

$$shape non - defective rate = number of individualized pieces with non - defective shape / total number \times 100$$

### Evaluation of Lighting Test

Lighting evaluation was also conducted on the mounting body in which the μLED element was mounted using the processed individualized pieces. The mounting body fabrication and lighting evaluation were performed as follows.

### Fabrication of Mounting Body

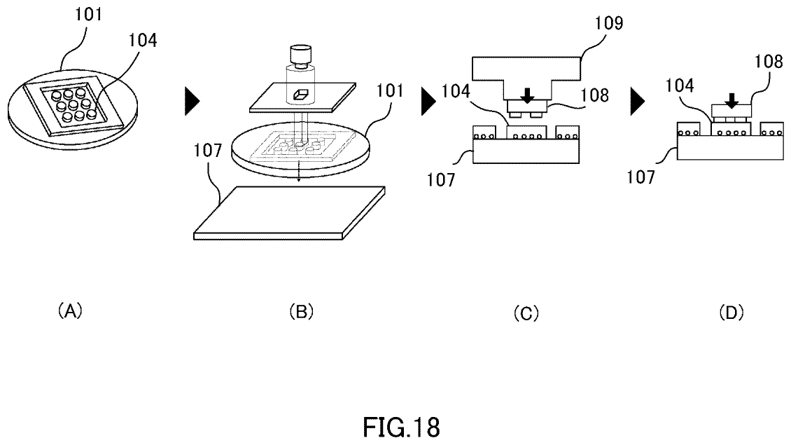

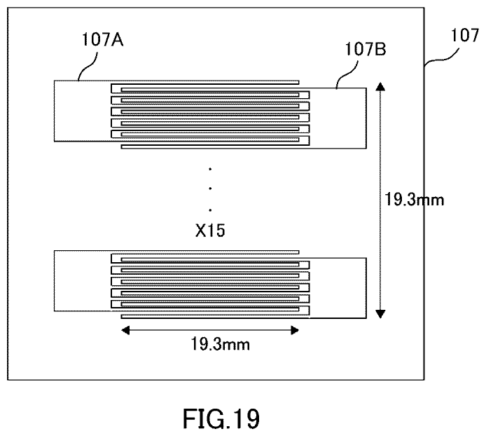

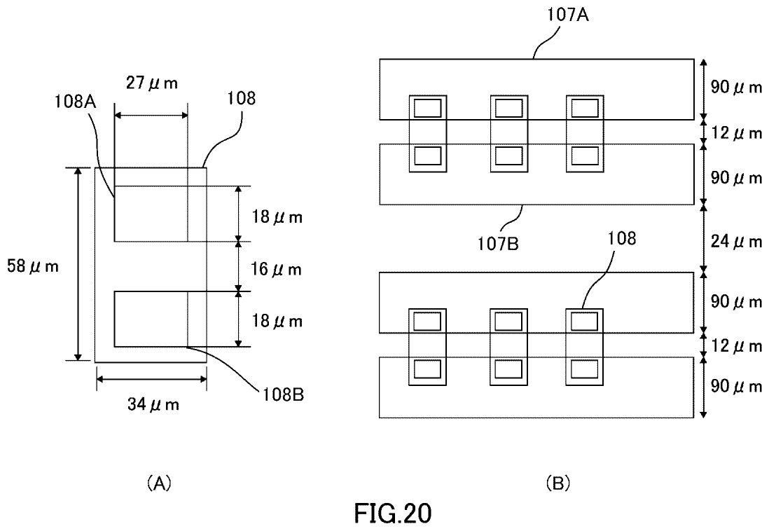

FIG. 18 schematically illustrates a fabrication method of a mounting body, in which FIG. 18 (A) shows the step of preparing individualized pieces, FIG. 18 (B) shows the step of transferring the individualized pieces to a substrate, FIG. 18 (C) shows the step of temporarily fixing a μLED element, and FIG. 18 (D) shows the step of pressure bonding the μLED element. FIG. 19 is a plan view schematically illustrating an evaluation substrate for a lighting test, FIG. 20 (A) is a plan view schematically illustrating an electrode surface of the μLED element, and FIG. 20 (B) is a plan view schematically illustrating a μLED element mounted on an evaluation substrate.

As shown in FIG. 18 (A), first, individualized pieces 104 of a predetermined shape processed on a quartz glass 101 as described above was prepared, and as shown in FIG. 18 (B), a laser was irradiated from the back (quartz glass 101 side) of the piece 104, thereby transferring the individualized pieces 104 to the designated locations on an evaluation substrate 107. The transfer of the individualized pieces 104 was performed in the same way as the LLO in the evaluation of the aforementioned individualized piece transfer.

The evaluation substrate 107 was made by forming a wiring pattern with an undercoat of 20 nm thick Cr and a front surface of 80 nm thick Au on a glass substrate 0.5 mm thick, which has, as shown in FIG. 27, 15 pairs of a first comb-shaped electrode 107A with 6 comb teeth and a second comb-shaped electrode 107B with 6 comb teeth. As shown in FIGS. 19 and 20 (B), the wiring pattern had the comb teeth with a line width of 90 μm and a space width of 12 μm or 24 μm, approximately 1,300 μm per channel×15 channels≈19.3 mm, and the individualized pieces of the predetermined shape were transferred between the wirings with a space width of 12 μm.

Next, as shown in FIG. 18 (C), a polydimethylsiloxane (PDMS) sheet 109 with μLED elements 108 arranged in the protruding portions was aligned in advance using LLO, and bonded under the conditions of 30° C., 30 MPa, and 10 sec, and as shown in FIG. 20 (B), the μLED elements 108 were temporarily fixed between the wirings with a space width of 12 μm on the evaluation substrate 107 via the individualized pieces 104.

As shown in FIG. 20 (A), the μLED element 108 used had an outer diameter of 34 μm×58 μm, with the size of the first electrode 108A and the second electrode 108B of 27 μm×18 μm, and the distance between the first electrode 108A and the second electrode 108B of 16 μm.

Next, as shown in FIG. 18 (D), the μLED elements 108 were all pressed together using a press with the pressing conditions of 150° C., 150 N, and 30 sec, thereby fabricating a mounting body with the μLED elements (total 3,600 pcs) mounted thereon.

### Lighting Evaluation

A voltage of 3.0V was applied to the first and second comb-shaped electrodes of the mounting body, and the number of lights was counted for all μLED elements (total 3,600 pcs), and the lighting rate was calculated using the following formula. The lighting rate should be 95% or more.

$$lighting rate = number of lights / total number \times 100$$

### Example 1

### Individualization Process of Anisotropic Conductive Film

First, 35 parts by mass of phenoxy resin (product name: PKHH, manufactured by Tomoe Engineering), 50 parts by mass of high-purity bisphenol A type epoxy resin (product name: YL-980, manufactured by Mitsubishi Chemical Corporation), 5 parts by mass of hydrophobic silica (product name: R202, manufactured by NIPPON AEROSIL), 7 parts by mass of cationic polymerization initiator (product name: SI-60L, manufactured by Sanshin Chemical Industry), and 3 parts by mass of silane coupling agent (product name: KBM-503, manufactured by Shin-Etsu Silicone) were blended to prepare a binder.

The binder was applied to a 50 μm thick PET film and dried to form a 4 μm thick resin film, and then an array sheet in which conductive particles (average particle diameter 2.2 μm, resin core metal-coated fine particles, Ni plating 0.1 μm thick, manufactured by Sekisui Chemical) were arranged in a hexagonal lattice with a particle density of 58,000 pcs/mm² was pasted to a resin film, and the conductive particles were pressed into the resin film to transfer them, thereby preparing an anisotropic conductive film with the conductive particles aligned. The conductive particle transfer side of the anisotropic conductive film was then pasted to a quartz glass plate to prepare an anisotropic conductive film substrate with a reference value closer to the base material, as shown in FIG. 1 (A).

As shown in Table 1, the melt viscosity of the anisotropic conductive film in Example 1 at 30° C. was 20,000 Pa*s. In addition, the presence rate of conductive particles relative to the reference value was 95%. The shape non-defective rate of the individualized pieces of the anisotropic conductive film substrate of Example 1 after the individualization process was 99% or more, and the lighting rate of the mounted bodies in which μLED elements were mounted using the individualized pieces was 99% or more.

### Example 2

An anisotropic conductive film substrate was fabricated in the same way as Example 1 except that the thickness of the resin film was 2 μm and the conductive particles were aligned in the anisotropic conductive film.

As shown in Table 1, the melt viscosity of the anisotropic conductive film in Example 2 at 30° C. was 20,000 Pa*s. In addition, the presence rate of conductive particles relative to the reference value was 99%. The shape non-defective rate of the individualized pieces of the anisotropic conductive film substrate of Example 2 after the individualization process was 99% or more, and the lighting rate of the mounted bodies in which μLED elements were mounted using the individualized pieces was 99% or more.

### Example 3

An anisotropic conductive film substrate was fabricated in the same way as Example 1 except that the thickness of the resin film was 10 μm and the conductive particles were aligned in the anisotropic conductive film.

As shown in Table 1, the melt viscosity of the anisotropic conductive film in Example 3 at 30° C. was 20,000 Pa*s. In addition, the presence rate of conductive particles relative to the reference value was 90%. The shape non-defective rate of the individualized pieces of the anisotropic conductive film substrate of Example 3 after the individualization process was 95%, and the lighting rate of the mounted bodies in which μLED elements were mounted using the individualized pieces was 95%.

### Example 4

An anisotropic conductive film substrate was fabricated in the same way as Example 1 except that the side opposite to the conductive particle transfer side of the anisotropic conductive film was pasted to a quartz glass plate so that the reference value was close to the opposite side of the base material, as shown in FIG. 1 (B).

As shown in Table 1, the melt viscosity of the anisotropic conductive film in Example 4 at 30° C. was 20,000 Pa*s. In addition, the presence rate of conductive particles relative to the reference value was 95%. The shape non-defective rate of the individualized pieces of the anisotropic conductive film substrate of Example 4 after the individualization process was 99% or more, and the lighting rate of the mounted bodies in which μLED elements were mounted using the individualized pieces was 99% or more.

### Example 5

An anisotropic conductive film substrate was fabricated in the same way as Example 1 except that, compared to Example 1, the amount of phenoxy resin was reduced and the amount of high-purity bisphenol A epoxy resin was increased to prepare an anisotropic conductive film with a melt viscosity of 2,000 Pa*s at 30° C.

As shown in Table 1, the melt viscosity of the anisotropic conductive film in Example 5 at 30° C. was 2,000 Pa*s. In addition, the presence rate of conductive particles relative to the reference value was 95%. The shape non-defective rate of the individualized pieces of the anisotropic conductive film substrate of Example 5 after the individualization process was 98%, and the lighting rate of the mounted bodies in which μLED elements were mounted using the individualized pieces was 98%.

### Example 6

An anisotropic conductive film substrate was fabricated in the same way as Example 1 except that, compared to Example 1, the amount of phenoxy resin was increased and the amount of high-purity bisphenol A epoxy resin was reduced to prepare an anisotropic conductive film with a melt viscosity of 800,000 Pa*s at 30° C.

As shown in Table 1, the melt viscosity of the anisotropic conductive film in Example 6 at 30° C. was 800,000 Pa*s. In addition, the presence rate of conductive particles relative to the reference value was 95%. The shape non-defective rate of the individualized pieces of the anisotropic conductive film substrate of Example 6 after the individualization process was 97%, and the lighting rate of the mounted bodies in which μLED elements were mounted using the individualized pieces was 97%.

### Example 7

An anisotropic conductive film substrate was fabricated in the same way as Example 1 except that an array sheet in which conductive particles (average particle diameter 2.2 μm, resin core metal-coated fine particles, Ni plating 0.1 μm thick, manufactured by Sekisui Chemical) were randomly arranged with a particle density of 58,000 pcs/mm² was pasted to a resin film, and the conductive particles were pressed into the resin film to transfer them, thereby producing an anisotropic conductive film with conductive particles randomly arranged.

As shown in Table 2, the melt viscosity of the anisotropic conductive film in Example 7 at 30° C. was 20,000 Pa*s. In addition, the presence rate of conductive particles relative to the reference value was 95%. The shape non-defective rate of the individualized pieces of the anisotropic conductive film substrate of Example 7 after the individualization process was 88%, and the lighting rate of the mounted bodies in which μLED elements were mounted using the individualized pieces was 86%.

### Example 8

An anisotropic conductive film substrate was fabricated in the same way as Example 7 except that the side opposite to the conductive particle transfer side of the anisotropic conductive film was pasted to a quartz glass plate so that the reference value was close to the opposite side of the base material, as shown in FIG. 1 (B).

As shown in Table 2, the melt viscosity of the anisotropic conductive film in Example 8 at 30° C. was 20,000 Pa*s. In addition, the presence rate of conductive particles relative to the reference value was 95%. The shape non-defective rate of the individualized pieces of the anisotropic conductive film substrate of Example 8 after the individualization process was 86%, and the lighting rate of the mounted bodies in which μLED elements were mounted using the individualized pieces was 85%.

### Comparative Example 1

An anisotropic conductive film substrate was fabricated in the same way as Example 1 except that the thickness of the resin film was 20 μm and the conductive particles were aligned in the anisotropic conductive film.

As shown in Table 2, the melt viscosity of the anisotropic conductive film in Comparative Example 1 at 30° C. was 20,000 Pa*s. In addition, the presence rate of conductive particles relative to the reference value was 95%. The shape non-defective rate of the individualized pieces of the anisotropic conductive film substrate of Comparative Example 1 after the individualization process was 0%.

### Comparative Example 2

An anisotropic conductive adhesive composition was prepared by mixing conductive particles (average particle diameter 2.2 μm, resin core metal-coated fine particles, Ni plating 0.1 μm thick, manufactured by Sekisui Chemical) into a binder so that the particle density was 58,000 pcs/mm². An anisotropic conductive film substrate was fabricated in the same way as Example 1 except that the anisotropic conductive adhesive composition was applied to a 50 μm-thick PET film and dried to form an anisotropic conductive film with a thickness of 4 μm, in which the conductive particles were dispersed in the thickness direction, as shown in FIG. 1 (C).

As shown in Table 2, the melt viscosity of the anisotropic conductive film in Comparative Example 2 at 30° C. was 20,000 Pa*s. In addition, the presence rate of conductive particles relative to the reference value was 70%. The shape non-defective rate of the individualized pieces of the anisotropic conductive film substrate of Comparative Example 2 after the individualization process was 73%, and the lighting rate of the mounted bodies in which μLED elements were mounted using the individualized pieces was 70%.

### Comparative Example 3

An anisotropic conductive film substrate was fabricated in the same way as Example 1 except that, compared to Example 1, the amount of phenoxy resin was reduced and the amount of high-purity bisphenol A epoxy resin was increased to prepare an anisotropic conductive film with a melt viscosity of 1,000 Pa*s at 30° C.

As shown in Table 2, the melt viscosity of the anisotropic conductive film in Comparative Example 3 at 30° C. was 1,000 Pa*s. In addition, the presence rate of conductive particles relative to the reference value was 95%. The shape non-defective rate of the individualized pieces of the anisotropic conductive film substrate of Comparative Example 3 after the individualization process was 80%, and the lighting rate of the mounted bodies in which μLED elements were mounted using the individualized pieces was 80%.

### Comparative Example 4

An anisotropic conductive film substrate was fabricated in the same way as Example 1 except that, compared to Example 1, the amount of phenoxy resin was increased and the amount of high-purity bisphenol A epoxy resin was reduced to prepare an anisotropic conductive film with a melt viscosity of 1,000,000 Pa*s at 30° C.

As shown in Table 2, the melt viscosity of the anisotropic conductive film in Comparative Example 4 at 30° C. was 1,000,000 Pa*s. In addition, the presence rate of conductive particles relative to the reference value was 95%. The shape non-defective rate of the individualized pieces of the anisotropic conductive film substrate of Comparative Example 4 after the individualization process was 76%, and the lighting rate of the mounted bodies in which μLED elements were mounted using the individualized pieces was 76%.

Table 1 shows the evaluation results for the shape non-defective rate for Examples 1 to 6, and Table 2 shows the evaluation results for the shape non-defective rate for Examples 7 and 8 and Comparative Examples 1 to 4.

TABLE 1

| | Ex. 1 | Ex. 2 | Ex. 3 | Ex. 4 | Ex. 5 | Ex. 6 |
|---|---|---|---|---|---|---|
| film thickness (μm) | 4 | 2 | 10 | 4 | 4 | 4 |
| ratio of film thickness to | 1.8 | 0.9 | 4.5 | 1.8 | 1.8 | 1.8 |
| conductive particle diameter | | | | | | |
| particle position status | FIG. | FIG. | FIG. | FIG. | FIG. | FIG. |
| | 1 (A) | 1 (A) | 1 (A) | 1 (B) | 1 (A) | 1 (A) |
| particle arrangement status | aligned | aligned | aligned | aligned | aligned | aligned |
| melt viscosity at 30° C. (Pa · s) | 20000 | 20000 | 20000 | 20000 | 2000 | 800000 |
| conductive particle presence ratio | 95 | 99 | 90 | 95 | 95 | 95 |
| relative to reference line (%) | | | | | | |
| shape non-defective rate (%) | >99 | >99 | 95 | >99 | 98 | 97 |
| lighting rate (%) | >99 | >99 | 95 | >99 | 98 | 97 |

TABLE 2

| | Ex. 7 | Ex. 8 | Comp. 1 | Comp. 2 | Comp. 3 | Comp. 4 |
|---|---|---|---|---|---|---|
| film thickness (μm) | 4 | 4 | 20 | 4 | 4 | 4 |
| ratio of film thickness to | 1.8 | 1.8 | 9.1 | 1.8 | 1.8 | 1.8 |
| conductive particle diameter | | | | | | |
| particle position status | FIG. | FIG. | FIG. | FIG. | FIG. | FIG. |
| | 1 (A) | 1 (B) | 1 (A) | 1 (C) | 1 (A) | 1 (A) |
| particle arrangement status | random | random | aligned | random | aligned | aligned |
| melt viscosity at 30° C. (Pa · s) | 20000 | 20000 | 20000 | 20000 | 1000 | 1000000 |
| conductive particle presence ratio | 95 | 95 | 95 | 70 | 95 | 95 |
| relative to reference line (%) | | | | | | |
| shape non-defective rate (%) | 88 | 86 | 0 | 73 | 80 | 76 |
| lighting rate (%) | 86 | 85 | — | 70 | 80 | 76 |

Comparative Example 1 had a shape non-defective rate of 0% because the thickness of the anisotropic conductive film was 20 μm. This is thought to be because the anisotropic conductive film did not tear because of the large thickness of the film. In Comparative Example 2, the shape non-defective rate was not good because the conductive particles in the anisotropic conductive film were dispersed in the thickness direction. This is thought to be because the degree of ablation was uneven. In Comparative Example 3, the shape non-defective rate was not good because the melt viscosity of the anisotropic conductive film at 30° C. was 1,000 Pa*s. This is thought to be because the anisotropic conductive film had a low melt viscosity at 30° C., so the individualized pieces shrank after laser irradiation, making it difficult to maintain the film of the individualized piece. In Comparative Example 4, the melt viscosity of the anisotropic conductive film at 30° C. was 1,000,000 Pa*s, so the film of the anisotropic conductive film was strong, and it is thought that it was difficult to remove the anisotropic conductive film by laser irradiation.

In Examples 1 to 8, the thickness of the anisotropic conductive film was 1 μm or more and 10 μm or less, the melt viscosity of the anisotropic conductive film at 30° C. was 2,000 Pa*s or more and 800,000 Pa*s or less, and 90% or more of the conductive particles were present in the anisotropic conductive film at the average of the center positions of the conductive particles in the thickness direction, so a good shape non-defective rate was obtained. In addition, in Examples 1 to 6, the conductive particles in the anisotropic conductive film were aligned in the surface direction, so a shape non-defective rate of 90% or more was obtained. This is thought to be because the degree of ablation in the surface direction is uniform.

In addition, by observing the outline of the individualized piece with a non-defective shape in Examples 1 to 8 with a metallurgical microscope, it was confirmed that the outline of the individualized piece was processed along the arrangement of the conductive particles. In other words, it was confirmed that the individualized pieces were torn along the arrangement of the conductive particles. In addition, the lighting rate in the lighting test for Examples 1 to 8 was the same as the shape non-defective rate of the individualized pieces.

### REFERENCE SIGNS LIST

1 substrate, 2A to 2C anisotropic conductive film, 3 conductive particles, 10 laser lift-off device, 11 laser scanner, 12 mask, 13 projection lens, 20 anisotropic conductive film substrate, 21 base material, 22 anisotropic conductive film, 23 removal portion, 30 anisotropic conductive film substrate, 31 base material, 32 anisotropic conductive film, 33 removal portion, 34 individualized piece, 41 individualized piece with burrs, 42 individualized piece with curling, 43 individualized piece with chips, 51 light-shielding portion, 52 individualized piece, 53 light-shielding portion, 54A to 54D light-shielding portions, 60 individualized-piece-film, 61 base material, 62 anisotropic conductive film, 63 conductive particles, 64 individualized piece, 64A individualized piece, 64B individualized piece, 70 wiring substrate, 71 base material, 72 first electrode, 73 second electrode, 80 light-emitting element, 81 main body, 82 first conductivity-type electrode, 83 second conductivity-type electrode, 90 transfer substrate, 91 base material, 101 quartz glass plate, 104 individualized piece, 107 evaluation substrate, 107A first comb-shaped electrode, 107B second comb-shaped electrode, 108 μLED element, 108A first electrode, 108B second electrode, 109 PDMS sheet

1-26. (canceled)

27. An individualized-piece-film including individualized pieces of a predetermined shape composed of an anisotropic conductive film, wherein
the thickness of the anisotropic conductive film is 0.9 times or more and 8 times or less of the particle diameter of the conductive particles in the anisotropic conductive film, and
the melt viscosity of the anisotropic conductive film at 30° C. is 2,000 Pa*s or more and 800,000 Pa*s or less.

28. The individualized-piece-film according to claim 27, wherein 90% or more of the conductive particles in the anisotropic conductive film are present at an average of the center positions of the conductive particles in the thickness direction of the anisotropic conductive film.

29. The individualized-piece-film according to claim 27, wherein the predetermined shape is at least one selected from a polygon with obtuse angles, a polygon with rounded corners, an ellipse, an oval, and a circle.

30. The individualized-piece-film according to claim 27, wherein the conductive particles in the anisotropic conductive film are aligned in a surface direction.

31. The individualized-piece-film according to claim 27, wherein the melt viscosity of the anisotropic conductive film at 30° C. is 5,000 Pa*s or more and 500,000 Pa*s or less.

32. A display device, comprising:
a plurality of light-emitting elements;
a wiring substrate on which the light-emitting elements are arranged; and
a cured film that connects the plurality of light-emitting elements to the wiring substrate, wherein
the cured film is made by curing individualized pieces of a predetermined shape composed of an anisotropic conductive film,
the thickness of the anisotropic conductive film is 0.9 times or more and 8 times or less of the particle diameter of the conductive particles in the anisotropic conductive film, and
the melt viscosity of the anisotropic conductive film at 30° C. is 2,000 Pa*s or more and 800,000 Pa*s or less.

33. The display device according to claim 32, wherein 90% or more of the conductive particles in the anisotropic conductive film are present at an average of the center positions of the conductive particles in the thickness direction of the anisotropic conductive film.

34. The display device according to claim 32, wherein the predetermined shape is at least one selected from a polygon with obtuse angles, a polygon with rounded corners, an ellipse, an oval, and a circle.

35. The display device according to claim 32, wherein the distance between the individualized pieces is 3 μm or more.

36. The display device according to claim 32, wherein the light-emitting elements are arranged in units of subpixels that constitute a pixel.

37. The display device according to claim 32, wherein the individualized pieces are arranged on the wiring substrate in units of subpixels or pixels.

38. A connection structure, comprising:
a first electronic component;
a second electronic component; and
a cured film connecting the first electronic component and the second electronic component, wherein
the cured film is made by curing individualized pieces of a predetermined shape composed of an anisotropic conductive film,
the thickness of the anisotropic conductive film is 0.9 times or more and 8 times or less of the particle diameter of the conductive particles in the anisotropic conductive film, and
the melt viscosity of the anisotropic conductive film at 30° C. is 2,000 Pa*s or more and 800,000 Pa*s or less.

39. The connection structure according to claim 38, wherein 90% or more of the conductive particles in the anisotropic conductive film are present at an average of the center positions of the conductive particles in the thickness direction of the anisotropic conductive film.

40. The connection structure according to claim 38, wherein the predetermined shape is at least one selected from a polygon with obtuse angles, a polygon with rounded corners, an ellipse, an oval, and a circle.

41. The connection structure according to claim 38, wherein the distance between the individualized pieces is 3 μm or more.

42. The connection structure according to claim 38, wherein the conductive particles in the anisotropic conductive film are aligned in a surface direction.

43. The connection structure according to claim 38, wherein the melt viscosity of the anisotropic conductive film at 30° C. is 5,000 Pa*s or more and 500,000 Pa*s or less.

44. The display device according to claim 32, wherein the conductive particles in the anisotropic conductive film are aligned in a surface direction.

45. The display device according to claim 32, wherein the melt viscosity of the anisotropic conductive film at 30° C. is 5,000 Pa*s or more and 500,000 Pa*s or less.
